(19) United States
(12) Patent Application Publication
(10) Pub. No.: US 2009/0009259 A1
(43) Pub. Date: Jan. 8, 2009

(54) ANGLE MODULATOR

(76) Inventors: Tomoaki Ohira, Osaka (JP); Kouichi Masuda, Osaka (JP); Masaru Fuse, Osaka (JP); Tsutomu Niiho, Osaka (JP)

Correspondence Address: WENDEROTH, LIND & PONACK L.L.P., 2033 K. STREET, NW, SUITE 800, WASHINGTON, DC, 20006, US

(21) Appl. No.: 12/160,290

(22) PCT Filed: Jan. 12, 2007
(86) PCT No.: PCT/JP2007/050293

§ 371 Date: Jul. 8, 2008

(30) Foreign Application Priority Data
Jan. 13, 2006 (JP) 2006-005972

(51) Int. Cl. H03C 3/02

(52) U.S. Cl. 332/119

(57) ABSTRACT

An angle modulator having an excellent noise characteristic and an excellent distortion characteristic independent of an unwanted wave component of an optical modulation signal is provided. The angle modulator (10) includes an optical SSB modulation section (103a), an optical SSB-SC modulation section (104a), and an optical angle modulation section (105). By performing intensity modulation on an output signal of the optical SSB modulation section (103a) at the optical SSB-SC modulation section (104a), an unwanted angle modulated signal is prevented from overlapping with an angle modulated signal outputted from an optical detection section (107). Further, by a filter (108) filtering only an angle modulated signal component which does not include the unwanted wave component among the angle modulated signal components outputted from the optical detection section (107), a distortion characteristic after angle demodulation can be prevented from deteriorating. Thus, the angle modulator according to the present invention can output an angle modulated signal having an excellent noise characteristic and an excellent distortion characteristic.

### TECHNICAL FIELD

The present invention relates to an angle modulator, and more particularly, to an angle modulator of an optical fiber transmission apparatus for transmitting a multichannel analog video signal or a multichannel digital video signal.

### BACKGROUND ART

Conventionally, as an angle modulator for converting a multichannel analog video signal or a multichannel digital video signal into a wideband angle modulated signal, there has been used an angle modulator having a configuration as shown in FIG. 13. An operation, and the like of such an angle modulator are described in detail, for example, in a document (K. Kikushima, et al., “Optical Super Wide-Band FM Modulation Scheme and Its Application to Multi-Channel AM Video Transmission Systems”, IOOC'95 Technical Digest, Vol. 5 PD2-7, pp. 33-34).

FIG. 13 is a view showing a configuration of a conventional angle modulator 90. As shown in FIG. 13, the angle modulator 90 includes an optical frequency control section 901, an optical modulation section 902, a local light source 903, an optical multiplexing section 904, and an optical detection section 905. A first signal source 906 outputs an electric signal to an angle modulator 90.

The electric signal outputted from the first signal source 906 is inputted to the optical modulation section 902. The electric signal is, for example, a signal obtained by frequency-multiplexing signals of frequencies f1 to fn. The optical modulation section 902 changes a frequency of light to be outputted in accordance with the inputted electric signal, thereby converting the electric signal outputted from the first signal source 906 into an optical frequency modulated signal.

The optical modulation section 902 is constructed of, for example, a semiconductor laser. Generally, when a certain current is applied to the semiconductor laser, the semiconductor laser emits light of a predetermined frequency fFM. Further, when an amplitude-modulated current is applied to the semiconductor laser, the semiconductor laser changes a frequency of light to be outputted in accordance with the applied current, and outputs an optical frequency modulated signal having the optical frequency fFM as a center frequency. Thus, the optical modulation section 902 converts the electric signal outputted from the first signal source 906 into the optical frequency modulated signal, and outputs the optical frequency modulated signal.

The local light source 903 outputs non-modulated light of a predetermined frequency fLocal.

The optical multiplexing section 904 multiplexes the optical signal outputted from the optical modulation section 902 and the light outputted from the local light source 903, and outputs a multiplexed optical signal.

The optical detection section 905 is constructed of, for example, a photodiode having a square-law detection characteristic. The optical detection section 905 performs optical heterodyne detection of the multiplexed optical signal outputted from the optical multiplexing section 904. More specifically, the optical detection section 905 outputs a difference beat signal having, as a center frequency, a frequency fc (=|fFM−fLocal|) corresponding to an optical frequency difference between the predetermined frequencies fFM and fLocal. By performing optical heterodyne detection of the inputted multiplexed optical signal, the optical detection section 905 outputs an angle modulated signal (a frequency modulated signal) of a carrier frequency fc which is originated from the electric signal outputted form the first signal source 906.

The optical frequency control section 901 controls the optical modulation section 902 and the local light source 903 such that a difference between the center frequency fFM of the optical signal outputted from the optical modulation section 902 and the optical frequency fLocal of the light outputted from the local light source 903 becomes constant, thereby stabilizing the center frequency fc of the angle modulated signal outputted from the optical detection section 905.

In the angle modulator 90, with a high modulation efficiency (a modulation efficiency which is ten times that of a modulation efficiency in a case of a common electric circuit mode) by optical signal processing, a wideband angle modulated signal (having a large frequency shift amount or a large phase shift amount) with an extremely high frequency, which is hard to generate by a common electric circuit, can be easily generated.

However, when a semiconductor laser is used as the optical modulation section 902, phase noise of the angle modulated signal outputted from the angle modulator 90 becomes large. The optical signals outputted from the optical modulation section 902 and the local light source 903 of the angle modulator 90 do not have a correlation in phase with each other. Thus, the phase noise of the angle modulated signal outputted from the angle modulator 90 is equivalent to a sum of phase noise of the optical signals outputted from the optical modulation section 902 and the local light source 903. An electric signal obtained by demodulating the angle modulated signal including the phase noise includes large white noise. Thus, the conventional angle modulator 90 has a problem that a quality of a demodulated signal significantly deteriorates due to this noise.

Further, for stabilizing the frequency of the angle modulated signal, the angle modulator 90 needs a control circuit (the optical frequency control section 901) which controls the frequencies of the optical signals outputted from the optical modulation section 902 and the local light source 903. Thus, the angle modulator 90 has a problem that a configuration thereof is complicated.

With respect to such problems, there has been proposed an angle modulator which while achieving angle modulation in an extremely high and wideband frequency band, suppresses phase noise with a simple configuration by optical signal processing, thereby improving a noise characteristic.

FIG. 14 is a view showing a configuration of a conventional angle modulator 91 which is disclosed in Patent Document 1. As shown in FIG. 14, the angle modulator 91 includes a light source 911, an optical branching section 912, an optical angle modulation section 913, an optical intensity modulation section 914, an optical multiplexing section 915, and an optical detection section 916.

The first light source 911 outputs non-modulated light of a predetermined frequency f0.

The optical branching section 912 branches the non-modulated light outputted from the first light source 911, and outputs branched non-modulated light as first light and second light.

To the optical angle modulation section 913, a frequency multiplexed first electric signal including frequency components of predetermined frequencies f1 to fn is inputted from a first signal source 906. The optical angle modulation section 913 performs optical angle modulation on the first light outputted from the optical branching section 912 in accordance with the inputted first electric signal, and outputs a resultant signal as a first optical signal. The first optical signal has the same phase noise as that of the light source 911. FIG. 16A is a schematic view showing an example of an optical spectrum of the first optical signal outputted from the optical angle modulation section 913.

To the optical intensity modulation section 914, a second electric signal having a predetermined frequency fc is inputted from a second signal source 917. The optical intensity modulation section 914 performs optical intensity modulation (optical amplitude modulation) on the second light outputted from the optical branching section 912 in accordance with the inputted second electric signal, and outputs a resultant signal as a second optical signal.

As the optical intensity modulation section 914, for example, there has been proposed a single sideband suppressed carrier optical intensity modulation section (herein after, referred to as an “optical SSB-SC modulation section”) in which at least three Mach-Zehnder interferometers (herein after, referred to as an “MZ interferometer”) are disposed on a crystal substrate such as a lithium niobate substrate, and the like.

FIG. 15 is a view showing a configuration of an optical SSB-SC modulation section 920. The optical SSB-SC modulation section 920 includes a first MZ interferometer 921, a second MZ interferometer 922, a third MZ interferometer 923, a branching section 924, a first phase inversion section 925, and a second phase inversion section 926.

The optical SSB-SC modulation section 920 branches the second light inputted from the optical branching section 912 into first and second optical carriers. The first optical carrier is inputted to the first MZ interferometer 921, and the second optical carrier is inputted to the second MZ interferometer 922.

The branching section 924 of the optical SSB-SC modulation section 920 branches a first electric signal fc1 inputted from the first signal source 906 into two electric signals, namely, an electric signal fc1a having the same phase as that of the first electric signal fc1 and an electric signal fc1b having a phase different from that of the first electric signal by 90°. The first phase inversion section 925 branches the electric signal fc1a into an electric signal fc1aa having the same phase as that of the electric signal fc1a and an electric signal fc1ab having a phase different from that of the electric signal fc1a by 180°, and outputs the branched electric signals to electrodes of the first MZ interferometer 921, respectively. On the other hand, the second phase inversion section 926 branches the electric signal fc1b into an electric signal fc1ba having a phase different from that of the electric signal fc1b by 90° and an electric signal fc1bb having a phase different from that of the electric signal fc1b by 270°, and outputs the branched electric signals to electrodes of the second MZ interferometer 922, respectively.

The first MZ interferometer 921 modulates the first optical carrier with the electric signal fc1aa and the electric signal fc1ab, adjusts a phase of the modulated first optical carrier with a first bias current V1, and outputs a resultant signal as a first optical intensity modulated signal. The second MZ interferometer 922 modulates the second optical carrier with the electric signal fc1ba and the electric signal fc1bb, adjusts a phase of the modulated second optical carrier with a second bias current V2, and outputs a resultant signal as a second optical intensity modulated signal. The third MZ interferometer 923 adjusts phases of the first and second optical intensity modulated signals with a third bias current V3, multiplexes two phase adjusted optical intensity modulated signals, and outputs a resultant signal. Thus, the optical SSB-SC modulation section 920 can perform optical SSB-SC modulation on the inputted light, and output a resultant signal as an optical intensity modulated signal.

FIG. 16B is a schematic view showing an example of an optical spectrum of an optical signal outputted from such an optical intensity modulation section (an optical SSB-SC modulation section) 914. As shown in FIG. 16B, in the second optical signal outputted from the optical intensity modulation section 914, an optical carrier component is suppressed, and the second optical signal has only a single sideband component which has been shifted from the optical carrier component by a frequency fc. The second optical signal has the same phase noise as that of the light source 911.

The optical multiplexing section 915 multiplexes the first optical signal outputted from the optical angle modulation section 913 and the second optical signal outputted from the optical intensity modulation section 1004, and outputs a resultant signal as a multiplexed optical signal.

The optical detection section 916 is constructed of, for example, a photodiode having a square-law detection characteristic. The optical detection section 916 performs optical homodyne detection of the multiplexed optical signal outputted from the optical multiplexing section 915 by using the square-law detection characteristic, and generates and outputs a difference beat signal between the first and second optical signals inputted to the optical multiplexing section 915. FIG. 16C is a schematic view showing an example of an optical spectrum of the difference beat signal outputted from the optical detection section 916. As shown in the figure, the difference beat signal is an angle modulated signal obtained by down-converting the first optical signal outputted from the optical angle modulation section 913, and its center frequency is fc.

The first and second optical signals each have the same phase noise as that of the light source 911. Even when the frequency of the first optical signal varies, the frequency of the second optical signal varies in the same manner. Thus, a frequency difference between these signals is constant regardless of the variation of the frequencies, the phase noise of the first and second optical signals are cancelled, and hence phase noise of the difference beat signal becomes constant. Therefore, according to the angle modulator shown in FIG. 14, theoretically, an angle modulated signal having an excellent noise characteristic can be obtained.

[Patent Document 1] Japanese Laid-Open Patent Publication No. 2001-133824 (Page 25, FIG. 1)

[Patent Document 2] Japanese Laid-Open Patent Publication No. 11-340926 (Page 18, FIG. 5)

### DISCLOSURE OF THE INVENTION

### Problems to be Solved by the Invention

However, the aforementioned optical SSB-SC modulator actually has a problem that it cannot suppress an optical single sideband component of an optical signal to be outputted due to errors concerning an optical branching ratio at each MZ interferometer and wavelength dependence of a waveguide, which occur in manufacturing.

FIG. 16D is a schematic view showing an example of an optical spectrum of an optical signal in which an optical carrier component and an optical single sideband component are not sufficiently suppressed. Depending on a vestigial optical carrier component G2 and a vestigial optical sideband component G3, a distortion characteristic significantly varies after the angle modulated signal outputted from the optical detection section 916 is demodulated.

FIG. 16E is a schematic view showing a spectrum of a signal outputted from the optical detection section 916 when the optical signal having the optical spectrum shown in FIG. 16D is outputted from the optical intensity modulation section (the optical SSB-SC modulation section) 914. As shown in FIG. 16E, a desired angle modulated signal E1 is generated as a difference beat component between the first optical signal outputted from the optical angle modulation section 913 and shown in FIG. 16A and a desired optical sideband component G1 shown in FIG. 16D. Similarly, an unwanted angle modulated signal E2 is generated from the first optical signal shown in FIG. 16A and the vestigial optical sideband component G3 shown in FIG. 16D. Still similarly, an unwanted angle modulated signal E3 is generated from the first optical signal shown in FIG. 16A and the vestigial optical carrier component G2 shown in FIG. 16D.

As shown in FIG. 16E, the unwanted angle modulated signal E2 has the same center frequency as that of the desired angle modulated signal E1 such that a signal band thereof overlaps with a signal band of the desired angle modulated signal E1, thereby deteriorating a distortion characteristic. Thus, the vestigial optical sideband component D3 in FIG. 16D is considered as a factor for causing the deterioration of the distortion characteristic. Further, as shown in FIG. 16E, when a level of the unwanted angle modulated signal E3 becomes large, the unwanted angle modulated signal E3 has a signal band which overlaps with the signal band of the desired angle modulated signal E1, thereby deteriorating the distortion characteristic. Thus, the vestigial optical carrier component G2 in FIG. 16D is considered as a factor for causing the deterioration of the distortion characteristic.

FIGS. 17A and 17B each are a view showing an experimental result concerning the above events. In FIG. 17A, a horizontal axis represents a suppression ratio of the vestigial optical sideband component G3 to the desired optical sideband component G1, and a vertical axis represents a distortion amount which is detected after an angle modulated signal is demodulated. Further, in FIG. 17B, a horizontal axis represents a suppression ratio of the vestigial optical carrier component G2 to the desired optical sideband component G1, and a vertical axis represents a distortion amount which is detected after an angle modulated signal is demodulated. FIGS. 17A and 17B show that the distortion amounts decrease in accordance with increases in the suppression ratios of the vestigial optical carrier component G2 and the vestigial optical sideband component G3 at any frequency of a demodulated signal. Therefore, the vestigial optical carrier component G2 and the vestigial optical sideband component G3 are considered to have an effect on the deterioration of the distortion characteristic.

With respect to such a problem, there is considered a technique of extracting a desired optical frequency component by filtering an optical modulation signal outputted from the optical intensity modulation section (the optical SSB-SC modulation section) 914 with an optical filter, or the like (e.g. refer to Patent Document 2). Patent Document 2 discloses usage of an optical band pass filter, and the like as the optical filter.

However, when a frequency interval between the desired optical sideband component G1 and the vestigial optical sideband component G3, namely, a carrier frequency of the desired angle modulated signal to be generated is, for example, a microwave band of about 10 GHz, the frequency interval is extremely narrow. However, a currently available optical filter has a bandwidth of about 50 GHz. Thus, there is a problem that the desired optical sideband component D1 cannot be singly filtered in a form of an optical signal.

For solving the above problems, an object of the present invention is to provide an angle modulator which has an optical intensity modulation section and an optical angle modulation section and is capable of improving a distortion characteristic of a transmission signal without using an optical filter by shifting center frequencies of a vestigial optical carrier component and a vestigial optical sideband component, and then multiplexing resultant optical signals.

### Solution to the Problems

To achieve the above objects, the present invention has the following aspects.

A first aspect of the present invention is an angle modulator for converting an input signal into an angle modulated signal, comprising: a light source; an optical branching section for branching light outputted from the light source into light propagating along a first path and light propagating along a second path; a first optical intensity modulation section provided on the first path for performing intensity modulation on inputted light with a second electric signal of a frequency fc2; a first optical angle modulation section provided on the second path for performing angle modulation on inputted light with an inputted signal; an optical multiplexing section for multiplexing the light propagating along the first path and the light propagating along the second path at ends of the first path and the second path; a second optical intensity modulation section provided in a stage prior to either the first optical intensity modulation section or the first optical angle modulation section for performing intensity modulation on inputted light with a first electric signal of a frequency fc1 different from the frequency fc2, and outputting intensity modulated light; and an optical detection section having a square-law detection characteristic for converting an optical signal outputted from the optical multiplexing section into an angle modulated signal.

According to the first aspect of the present invention, an effect of an unwanted angle modulated signal, which is generated by detecting light including a vestigial optical carrier component and a vestigial optical single sideband component, on a desired angle modulated signal is suppressed, and a input signal can be transmitted as a wideband angle modulated signal having an excellent noise characteristic and an excellent distortion characteristic.

In a second aspect of the present invention according to the first aspect, the second optical intensity modulation section may be provided in a stage prior to the first optical intensity modulation section for performing optical SSB modulation on inputted light, and the first optical intensity modulation section may perform optical SSB-SC modulation on optical SSB modulated light.

According to the second aspect of the present invention, for suppressing an effect of an unwanted angle modulated signal among angle modulated signals on an angle modulated signal having a desired carrier frequency, a vestigial optical single sideband component can be shifted to a desired frequency band.

In a third aspect of the present invention according to the second aspect, where a bandwidth of an optical signal outputted from the optical angle modulation section is B, |fc1−fc2|>B/2 and 2×fc2−fc1>B may be satisfied.

According to the third aspect of the present invention, the unwanted angle modulated signal among the angle modulated signals can be prevented from overlapping with the angle modulated signal having the desired carrier frequency.

In a fourth aspect of the present invention according to the first aspect, the second optical intensity modulation section may be provided in a stage prior to the first optical intensity modulation section for performing optical SSB-SC modulation on inputted light, and the first optical intensity modulation section may perform optical SSB modulation on optical SSB-SC modulated light.

According to the fourth aspect of the present invention, for suppressing an effect of the unwanted angle modulated signal among the angle modulated signals on the angle modulated signal having the desired carrier frequency, the vestigial optical single sideband component can be shifted to the desired frequency band.

In a fifth aspect of the present invention according to the fourth aspect, where a bandwidth of an optical signal outputted from the optical angle modulation section is B,|fc1−fc2|>B/2 and 2×fc2−fc1>B may be satisfied.

According to the fifth aspect of the present invention, the unwanted angle modulated signal among the angle modulated signals is prevented from overlapping with the angle modulated signal having the desired carrier frequency.

In a sixth aspect of the present invention according to the first aspect, the second optical intensity modulation section may be provided in a stage prior to the first optical angle modulation section.

According to the sixth aspect of the present invention, an effect of a vestigial carrier component, which is generated in the same frequency as that of the desired angle modulated signal having the carrier frequency, on the angle modulated signal having the desired carrier frequency can be suppressed.

In a seventh aspect of the present invention according to the sixth aspect, the first optical intensity modulation section may perform optical SSB-SC modulation on inputted light, the second optical intensity modulation section may perform optical SSB-SC modulation on inputted light, and the first optical angle modulation section may perform angle modulation on optical SSB-SC modulated light with the input signal.

According to the seventh aspect of the present invention, for suppressing the effect of the vestigial carrier component, which is generated in the same frequency as that of the angle modulated signal having the desired carrier frequency, on the angle modulated signal having the desired carrier frequency, the vestigial optical single sideband component and the vestigial optical carrier component can be shifted to the desired frequency band.

In an eighth aspect of the present invention according to the seventh aspect, the angle modulator may further comprise an optical delay adjustment section provided in a stage after the first optical intensity modulation section for delaying propagation of the light propagating along the first path such that a propagation delay amount of the light propagating along the first path is equalized with a propagation delay amount of the light propagating along the second path.

According to the eighth aspect of the present invention, the effect of the vestigial carrier component, which is generated in the same frequency as that of the angle modulated signal having the desired carrier frequency, on the angle modulated signal having the desired carrier frequency can be suppressed further.

In a ninth aspect of the present invention according to the sixth aspect, the second optical intensity modulation section may include: a first optical DSB modulation section for performing optical DSB modulation on the branched light propagating along the second path with the first electric signal and with an electric signal obtained by shifting a phase of the first electric signal by 180°; and a second optical DSB modulation section for performing optical DSB modulation on the branched light propagating along the second path with an electric signal obtained by shifting the phase of the first electric signal by 90° and with an electric signal obtained by further shifting the phase of the first electric signal by 180° after shifting the phase of the first electric signal by 90°, and the first optical angle modulation section may perform optical angle modulation on light outputted from the first optical DSB modulation section and light outputted from the second optical DSB modulation section with the input signal, respectively, and may multiplex light obtained by performing optical angle modulation on the light outputted from the first optical DSB modulation section and light obtained by performing optical angle modulation on the light outputted from the second optical DSB modulation section.

According to the ninth aspect of the present invention, two components, namely, the second optical intensity modulation section and the first optical angle modulation section, can be integrated into a single component, thereby providing an angle modulator with a simple configuration.

In a tenth aspect of the present invention according to the sixth aspect, the angle modulator may further comprise: a phase inversion section for branching the input signal into an in-phase signal having the same phase as a phase of the input signal and a reverse-phase signal obtained by inverting the phase of the input signal; and a second optical angle modulation section provided in a stage after the first optical intensity modulation section for performing optical angle modulation on inputted light with an inputted signal, and the first optical angle modulation section may perform angle modulation on inputted light with the in-phase signal.

According to the tenth aspect of the present invention, a phase shift amount of an angle modulated signal can be increased by performing optical angle modulation with the inputted signal and with a signal obtained by inverting the phase of the inputted signal.

In an eleventh aspect of the present invention according to the tenth aspect, the first optical intensity modulation section may perform optical SSB-SC modulation on inputted light, and the second optical intensity modulation section may perform optical SSB-SC modulation on inputted light.

According to the eleventh aspect of the present invention, the effect of the vestigial carrier component, which is generated in the same frequency as that of the angle modulated signal having the desired carrier frequency, on the angle modulated signal having the desired carrier frequency can be suppressed, and the phase shift amount of the angle modulated signal can be increased.

In a twelfth aspect of the present invention according to the tenth aspect, the second optical intensity modulation section may include: a first optical DSB modulation section for performing optical DSB modulation on the branched light propagating along the second path with the first electric signal and with an electric signal obtained by shifting a phase of the first electric signal by 180°; and a second optical DSB modulation section for performing optical DSB modulation on the branched light propagating along the second path with an electric signal obtained by shifting the phase of the first electric signal by 90° and with an electric signal obtained by further shifting the phase of the first electric signal by 180° after shifting the phase of the first electric signal by 90°, and the first optical intensity modulation section may include: a third optical DSB modulation section for performing optical DSB modulation on the branched light propagating along the first path with the second electric signal and with an electric signal obtained by shifting a phase of the second electric signal by 180°; and a fourth optical DSB modulation section for performing optical DSB modulation on the branched light propagating along the first path with an electric signal obtained by shifting the phase of the second electric signal by 90° and with an electric signal obtained by further shifting the phase of the second electric signal by 180° after shifting the phase of the second electric signal by 90°. The first optical angle modulation section may perform optical angle modulation on light outputted from the first optical DSB modulation section and light outputted from the second optical DSB modulation section with the in-phase signal, respectively, and may multiplex light obtained by optical angle modulation on the light outputted from the first optical DSB modulation section and light obtained by optical angle modulation on the light outputted from the second optical DSB modulation section, and the second optical angle modulation section may perform optical angle modulation on light outputted from the third optical DSB modulation section and light outputted from the fourth optical DSB modulation section with the reverse-phase signal, respectively, and may multiplex light obtained by performing optical angle modulation on the light outputted from the third optical DSB modulation section and light obtained by performing optical angle modulation on the light outputted from the fourth optical DSB modulation section.

According to the twelfth aspect of the present invention, the second optical intensity modulation section and the first optical angle modulation section, the first optical intensity modulation section and the second optical angle modulation section can be integrated into single components, respectively, thereby providing an angle modulator capable of increasing a phase shift amount of an angle modulated signal with a simple configuration.

In a thirteenth aspect of the present invention according to any one of the seventh aspect and the ninth aspect, where among angle modulated signals outputted from the optical detection section, a bandwidth of an angle modulated signal having a center frequency of |fc1−fc2| is B1 and a bandwidth of an angle modulated signal having a center frequency of fc1 is B2, when fc1<fc2, |fc1−fc2|≧B1/2 and |fc1−fc2|+B1/2<fc1−B2/2 may be satisfied.

According to the thirteenth aspect of the present invention, when fc1<fc2, the unwanted angle modulated signal among the angle modulated signals can be prevented from overlapping with the angle modulated signal having the desired carrier frequency.

In a fourteenth aspect of the present invention according to any one of the seventh aspect and the ninth aspect, where among angle modulated signals outputted from the optical detection section, a bandwidth of an angle modulated signal having a center frequency of |fc1−fc2| is B1 and a bandwidth of an angle modulated signal having a center frequency of fc2 is B3, when fc1>fc2, |fc1−fc2|≧B1/2 and |fc1−fc2|+B1/2<fc2−B3/2 may be satisfied.

According to the present invention, when fc1>fc2, the unwanted angle modulated signal among the angle modulated signals can be prevented from overlapping with the angle modulated signal having the desired carrier frequency.

### BRIEF DESCRIPTION OF THE DRAWINGS

FIG. 1 is a block diagram showing a configuration of an angle modulator according to a first embodiment of the present invention.

FIG. 2A is a schematic view showing an example of a spectrum of an optical signal outputted from an optical SSB modulation section shown in FIG. 1.

FIG. 2B is a schematic view showing an example of a spectrum of an optical signal outputted from an optical SSB-SC modulation section shown in FIG. 1.

FIG. 2C is a schematic view showing an example of a spectrum of an angle modulated signal outputted from an optical angle modulation section shown in FIG. 1.

FIG. 2D is a schematic view showing an example of a spectrum of an angle modulated signal outputted from an optical detection section shown in FIG. 1.

FIG. 3 is a block diagram showing a configuration of an angle modulator according to a second embodiment of the present invention.

FIG. 4A is a schematic view showing an example of a spectrum of an optical signal outputted from an optical SSB-SC modulation section shown in FIG. 3.

FIG. 4B is a schematic view showing an example of a spectrum of an optical signal outputted from an optical SSB modulation section shown in FIG. 3.

FIG. 4C is a schematic view showing an example of a spectrum of an angle modulated signal outputted from an optical detection section shown in FIG. 3.

FIG. 5 is a block diagram showing a configuration of an angle modulator according to a third embodiment of the present invention.

FIG. 6A is a schematic view showing an example of a spectrum of non-modulated light outputted from a light source shown in FIG. 5.

FIG. 6B is a schematic view showing an example of a spectrum of an optical signal outputted from a first optical SSB-SC modulation section 303 shown in FIG. 5.

FIG. 6C is a schematic view showing an example of a spectrum of an optical signal outputted from a second optical SSB-SC modulation section 304 shown in FIG. 5.

FIG. 6D is a schematic view showing an example of a spectrum of an optical signal outputted from an optical angle modulation section shown in FIG. 5.

FIG. 6E is a schematic view showing an example of a spectrum of an angle modulated signal outputted from an optical detection section shown in FIG. 5.

FIG. 7 is a block diagram showing a configuration of an angle modulator according to a modified example of the third embodiment of the present invention.

FIG. 8 is a block diagram showing a configuration of an angle modulator according to a modified example of the third embodiment of the present invention.

FIG. 9 is a schematic view showing a configuration of an optical modulator shown in FIG. 8.

FIG. 10A is a schematic view showing an example of a spectrum of an angle modulated optical signal outputted from a first MZ interferometer shown in FIG. 9.

FIG. 10B is a schematic view showing an example of a spectrum of an angle modulated optical signal outputted from a second MZ interferometer shown in FIG. 9.

FIG. 11 is a block diagram showing a configuration of an angle modulator according to a fourth embodiment of the present invention.

FIG. 12 is a block diagram showing a configuration of an angle modulator according to a modified example of the fourth embodiment of the present invention.

FIG. 13 is a block diagram showing a configuration of a conventional angle modulator.

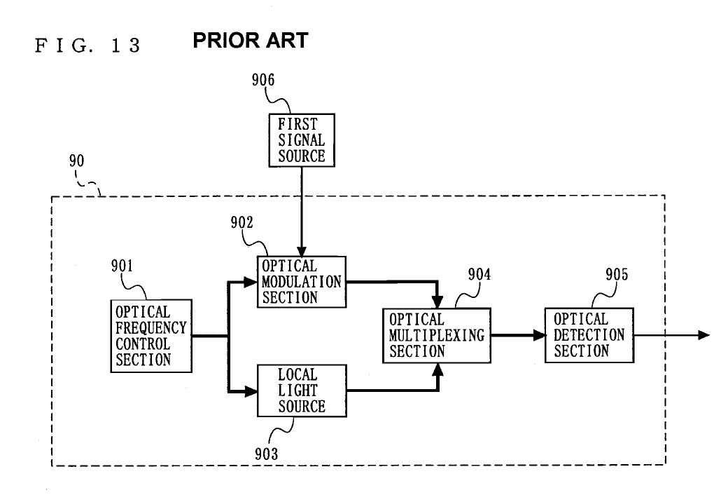

FIG. 14 is a block diagram showing a configuration of a conventional angle modulator.

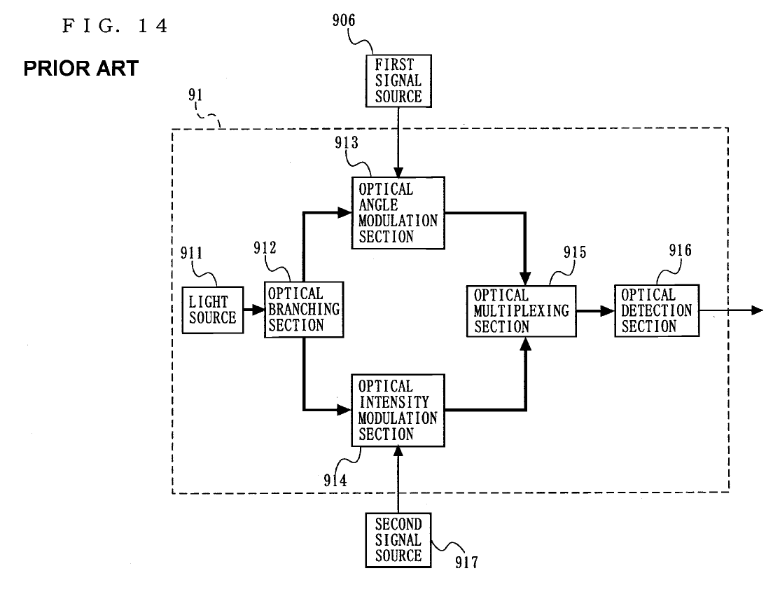

FIG. 15 is a block diagram showing a configuration of an optical intensity modulation section shown in FIG. 14.

FIG. 16A is a schematic view showing an example of a spectrum of an optical signal outputted from an optical angle modulation section shown in FIG. 14.

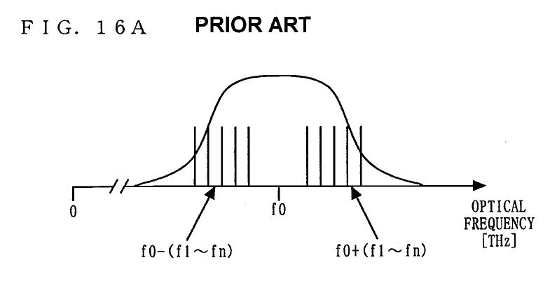

FIG. 16B is a schematic view showing an example of a spectrum of an optical signal outputted from an optical intensity modulation section shown in FIG. 14.

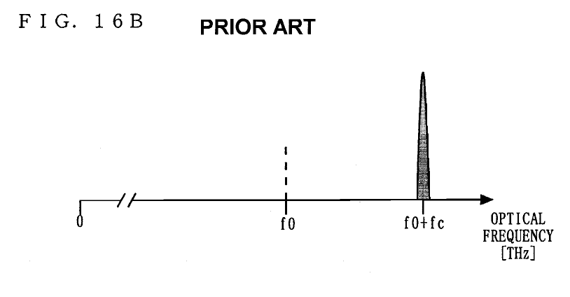

FIG. 16C is a schematic view showing an example of a spectrum of a difference beat signal outputted from an optical detection section shown in FIG. 14.

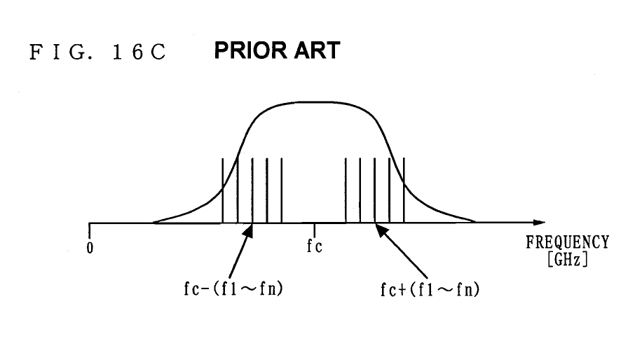

FIG. 16D is a view showing an example of a spectrum of an optical signal in which an optical carrier component and an optical single sideband component are not sufficiently suppressed.

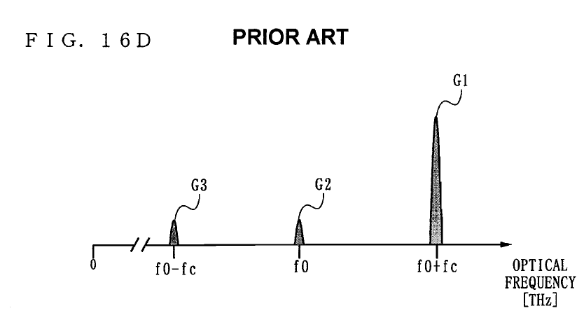

FIG. 16E is a schematic view showing an example of a spectrum of a difference beat signal outputted when the optical detection section shown in FIG. 14 detects an optical signal having the optical spectrum shown in FIG. 16D.

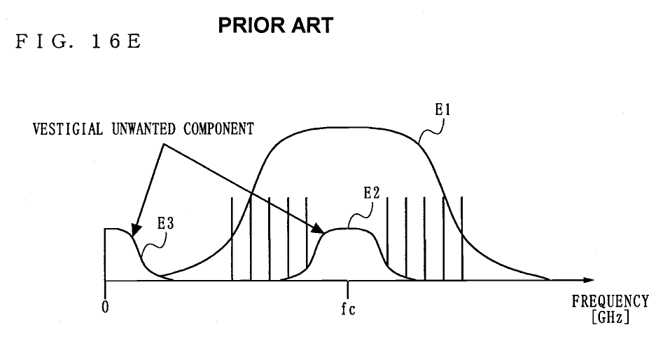

FIG. 17A is a view showing a correlation between a suppression ratio of an unwanted vestigial sideband component for an angle modulated signal outputted from the conventional angle modulator and a distortion characteristic after demodulation.

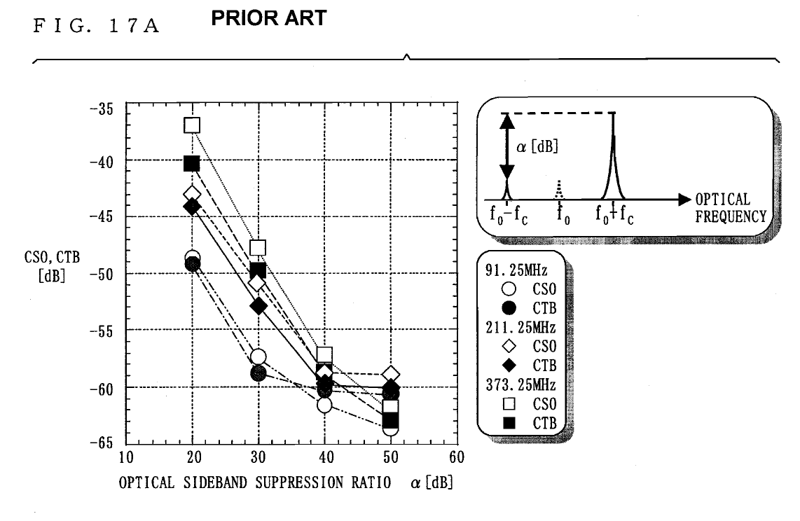

FIG. 17B is a view showing a correlation between a suppression ratio of an unwanted vestigial optical carrier component for an angle modulated signal outputted from the conventional angle modulator and a distortion characteristic after demodulation.

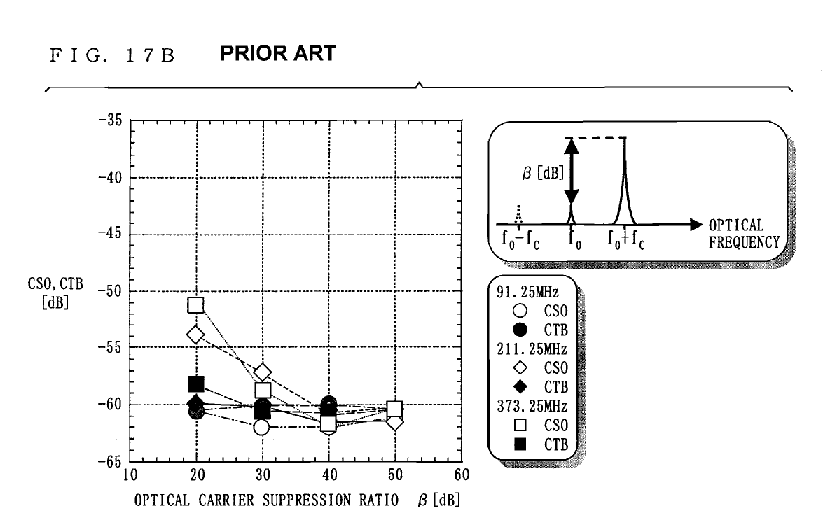

### DESCRIPTION OF THE REFERENCE CHARACTERS

10, 20, 30, 31, 32, 40, 41 angle modulator
101, 301 light source
102, 302 optical branching section
103a, 103b optical SSB modulation section (single sideband optical intensity modulation section)
104a, 103b optical SSB-SC modulation section (single sideband suppressed carrier optical intensity modulation section)
303 first optical SSB-SC modulation section (single sideband suppressed carrier optical intensity modulation section)
304 second optical SSB-SC modulation section (single sideband suppressed carrier optical intensity modulation section)
105, 305 optical angle modulation section
106, 306 optical multiplexing section
107, 307 optical detection section
108, 308 filter
109. 310 first signal source
110, 309 second signal source
111, 311 third signal source
3211 first MZ interferometer
3212 second MZ interferometer
3213 third MZ interferometer
3214 first branching section
3215 first phase inversion section
3216 second phase inversion section
3217 second branching section
3218, 3227 optical intensity modulation section
3219, 3228 optical angle modulation section
E1 first electric signal
E2 second electric signal
E3 third electric signal
E4a electric signal
E4b inversion signal
Oc multiplexed optical signal
Db difference beat signal

### BEST MODE FOR CARRYING OUT THE INVENTION

### First Embodiment

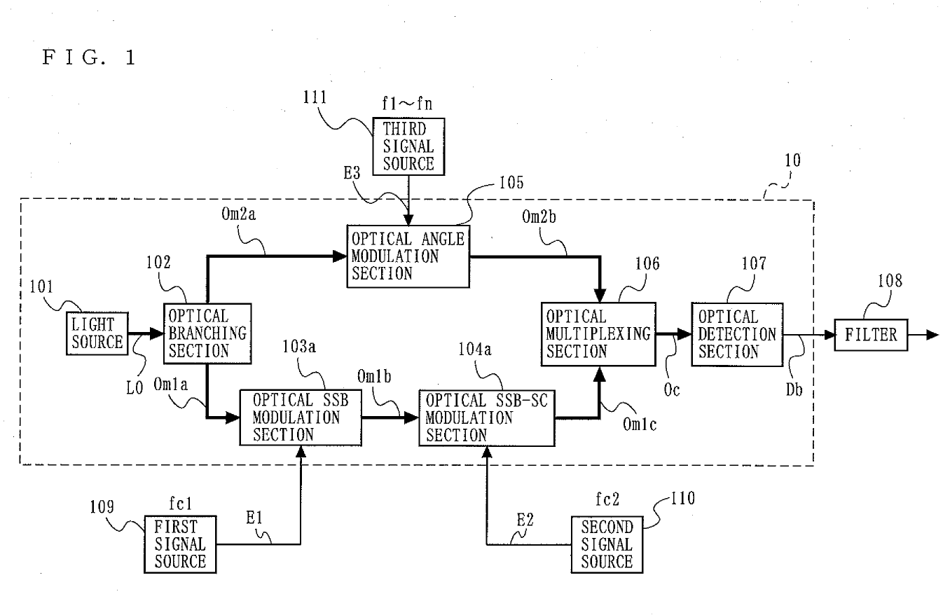

The following will describe a first embodiment of the present invention with reference to the figures. FIG. 1 is a block diagram showing a configuration of an angle modulator 10 according to the embodiment of the present invention. As shown in FIG. 1, the angle modulator 10 includes a light source 101, an optical branching section 102, a single sideband optical intensity modulation section (herein after, referred to as an “optical SSB modulation section”) 103a, a single sideband suppressed carrier optical intensity modulation section (herein after, referred to as an “optical SSB-SC modulation section”) 104a, an optical angle modulation section 105, an optical multiplexing section 106, and an optical detection section 107. In the first embodiment, the optical SSB-SC modulation section 104a functions as a first optical intensity modulation section recited in the CLAIMS, and the optical SSB modulation section 103a functions as a second optical intensity modulation section recited in the CLAIMS.

The light source 101 outputs non-modulated light L0 of a predetermined frequency f0.

The optical branching section 102 branches the non-modulated light L0 outputted from the light source 101, and outputs first light Om1a and second light Om2a.

To the optical SSB modulation section 103a, the first light Om1a and a first electric signal E1 outputted from a first signal source 109 and having a predetermined frequency fc1 are inputted. The optical SSB modulation section 103a performs optical SSB modulation on the first light Om1a in accordance with amplitude of the first electric signal E1, and outputs a modulated signal as a first optical signal Om1b.

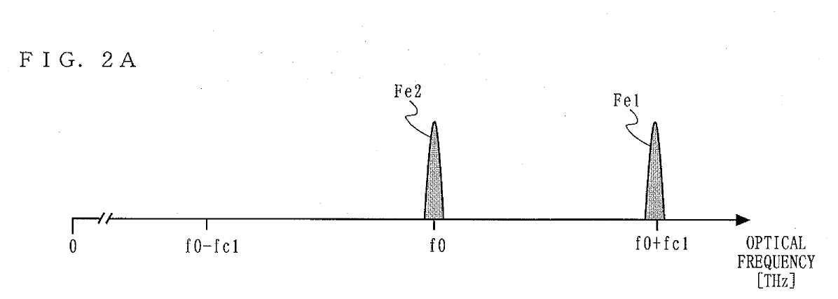

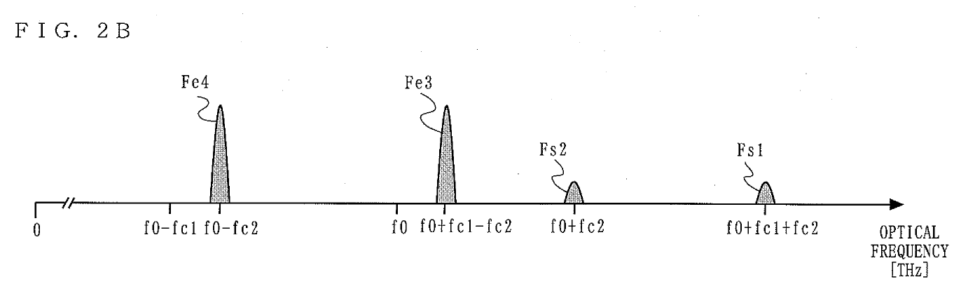

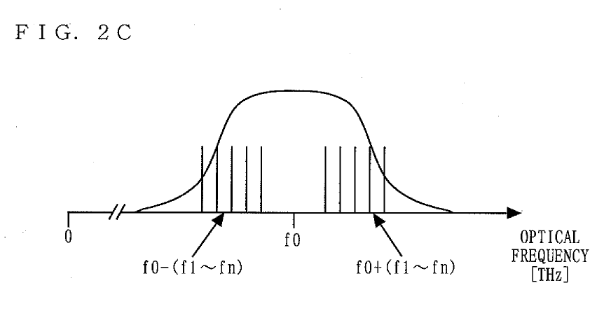

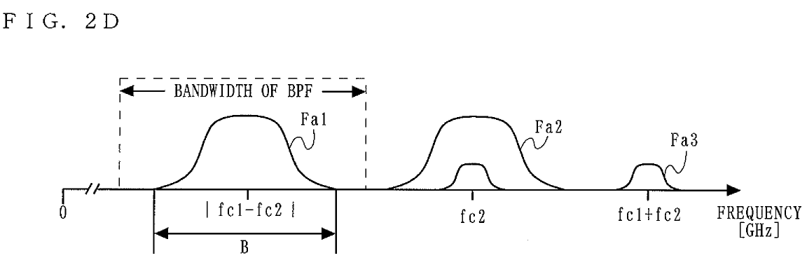

FIG. 2A is a view showing an example of an optical spectrum of the first optical signal Om1b outputted from the optical SSB modulation section 103a. As shown in FIG. 2A, the first optical signal Om1b is an optical modulation signal including an optical carrier component and an optical single sideband component.

To the optical SSB-SC modulation section 104a, the first optical signal Om1b and a second electric signal E2 outputted from a second signal source 110 and having a predetermined frequency fc2 are inputted. The optical SSB-SC modulation section 104a performs optical SSB-SC modulation on the first optical signal Om1b in accordance with amplitude of the second electric signal E2, and outputs the optical SSB-SC modulated first optical signal Om1b as a second optical signal Om1c.

FIG. 2B is a view showing an example of a spectrum of the second optical signal Om1c outputted from the optical SSB-SC modulation section 104a. As shown in FIG. 2B, the second optical signal Om1c is a single sideband suppressed carrier optical modulation signal including a frequency component Fe3 corresponding to a frequency component Fe1 in FIG. 2A and a frequency component Fe4 corresponding to a frequency component Fe2 in FIG. 2A. In addition, as shown in FIG. 2B, the second optical signal Om1c includes a vestigial single sideband component Fs1 corresponding to the frequency component Fe1 and a vestigial single sideband component Fs2 corresponding to the frequency component Fe2.

To the optical angle modulation section 105, the second light Om2a and a third electric signal E3 outputted from a third signal source 111 are inputted. For example, the third electric signal E3 is a signal obtained by multiplexing signals of frequencies f1 to fn. The optical angle modulation section 105 performs optical angle modulation (optical phase modulation or optical frequency modulation) on the second light Om2a in accordance with amplitude of the third electric signal E3, and outputs the optical angle modulated second light Om2a as a third optical signal Om2b. FIG. 2C is a schematic view showing an example of a spectrum of the third optical signal Om2b outputted from the optical angle modulation section 105.

The optical multiplexing section 106 multiplexes the second optical signal Om1c outputted from the optical SSB-SC modulation section 104a and the third optical signal Om2b outputted from the optical angle modulation section 105, and outputs a multiplexed optical signal Oc.

The optical detection section 107 is constructed of, for example, a photodiode having a square-law detection characteristic. The optical detection section 107 performs optical homodyne detection of the multiplexed optical signal Oc outputted from the optical multiplexing section 106 by using the square-law detection characteristic, and generates and outputs a difference beat signal Db between these signals. The difference beat signal Db is a signal obtained by down-converting the third optical signal Om2b.

FIG. 2D is a view showing an example of a spectrum of the difference beat signal Db outputted from the optical detection section 107. As shown in FIG. 2D, the difference beat signal Db includes an angle modulated signal component Fa1 having a center frequency of |fc1−fc2|, a angle modulated signal Fa2 having a center frequency of fc2 and including an unwanted wave component, an unwanted wave component Fa3 having a center frequency of (fc1+fc2).

As shown in FIG. 2D, the angle modulated signal component Fa1 is a difference beat signal component obtained by down-converting the frequency component Fe3 shown in FIG. 2B to have the center frequency of |fc1−fc2|. The angle modulated signal Fa2 including the unwanted wave component is a difference beat signal component obtained by down-converting the frequency component Fe4 and the vestigial single sideband component Fs2 to have the frequency fc2 such that these components overlap with each other. The unwanted wave component Fa3 is a difference beat signal component obtained by down-converting the vestigial single sideband component Fs1 to have the center frequency of (fc1+fc2). Thus, the vestigial single sideband components do not overlap with the angle modulated signal component Fa1. Further, by selecting the frequencies fc1 and fc2 such that |fc1−fc2| becomes a predetermined carrier frequency, an angle modulated signal of a desired carrier frequency which is not affected by the vestigial single sideband components can be obtained.

The angle modulator 10 outputs an angle modulated signal which does not include an unwanted frequency component by filtering only the angle modulated signal component Fa1 included in the difference beat signal Db shown in FIG. 2D. Thus, overlapping of other frequency components with the angle modulated signal component Fa1 has to be avoided. For that reason, where a signal bandwidth of the third optical signal Om2b is B, the bandwidth B, the frequency fc1, and the frequency fc2 need to satisfy a condition of |fc1−fc2|>B/2 and (2×fc2−fc1)<B.

As described above, by performing optical SSB modulation on the non-modulated light L0 of the frequency f0 and performing optical SSB-SC modulation on the optical SSB modulated optical modulation signal, the angle modulator 10 can shift the vestigial sideband component generated at the optical SSB-SC modulation section to have a center frequency which is different from a desired center frequency. Thus, according to the angle modulator 10 according to the present embodiment, a distortion characteristic of a signal obtained by demodulating the angle modulated signal is prevented from deteriorating due to overlapping of an unwanted angle modulated signal component, which is generated by detecting light including a vestigial optical carrier component and a vestigial optical single sideband component, with a desired angle modulated signal component.

It is noted that as shown in FIG. 1, the angle modulator 10 may further include a filter 108. The filter 108 allows only an angle modulated signal component of the desired center frequency among the difference beat signal Db outputted from the optical detection section 107 to pass therethrough. The filter 108 is, for example, a band pass filter which extracts only an angle modulated signal component having the center frequency |fc1−fc2| as indicated by a dashed line in FIG. 2D. By further including the filter 108, the angle modulator 10 removes a single sideband component of an angle modulated signal unwanted for the angle modulated signal having the desired carrier frequency, thereby providing a wideband angle modulated signal having an excellent noise characteristic and an excellent distortion characteristic.

For example, even when a low pass filter capable of extracting only an angle modulated signal having the center frequency of |fc1−fc2| is used as the filter 108, the same advantageous effect as that in the present embodiment is obtained.

### Second Embodiment

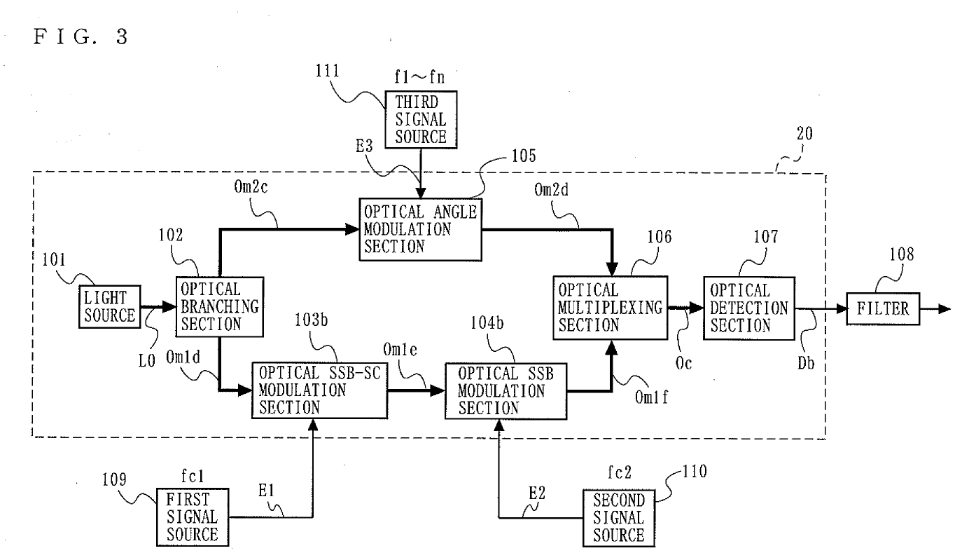

A second embodiment of the present invention will be described with reference to the figures. FIG. 3 is a block diagram showing a configuration of an angle modulator 20 according to the present invention. As shown in FIG. 3, the angle modulator 20 includes a light source 101, an optical branching section 102, an optical SSB-SC modulation section 103b, an optical SSB modulation section 104b, an optical angle modulation section 105, an optical multiplexing section 106, and an optical detection section 107. In the second embodiment, the optical SSB modulation section 104b functions as the first optical intensity modulation section recited in the CLAIMS, and the optical SSB-SC modulation section 103b functions as the second optical intensity modulation section recited in the CLAIMS.

In the angle modulator 20 according to the present embodiment, the positions of the two optical intensity modulation sections of the angle modulator 10 according to the first embodiment are switched. In other words, concerning the difference between the angle modulator 20 according to the present embodiment and the angle modulator 10 according to the first embodiment, the angle modulator 10 has a configuration in which the non-modulated light L0 of the frequency f0 outputted from the light source 101 is subjected to optical SSB modulation and the optical SSB modulated optical modulation signal is subjected to optical SSB-SC modulation, while the angle modulator 20 has a configuration in which the non-modulated light L0 of the frequency f0 outputted from the light source 101 is subjected to optical SSB-SC modulation and the optical SSB-SC modulated optical modulation signal is subjected to optical SSB modulation. In the present embodiment, the same or corresponding parts as those of the angle modulator 10 according to the first embodiment are designated by the same reference characters, and the description thereof will be omitted.

To the optical SSB-SC modulation section 103b, first light Om1d and a first electric signal E1 outputted from the first signal source 109 and having a predetermined frequency fc1 are inputted. The optical SSB-SC modulation section 103b performs optical SSB-SC modulation on the first light Om1d, and outputs a resultant signal as a first optical signal Om1e.

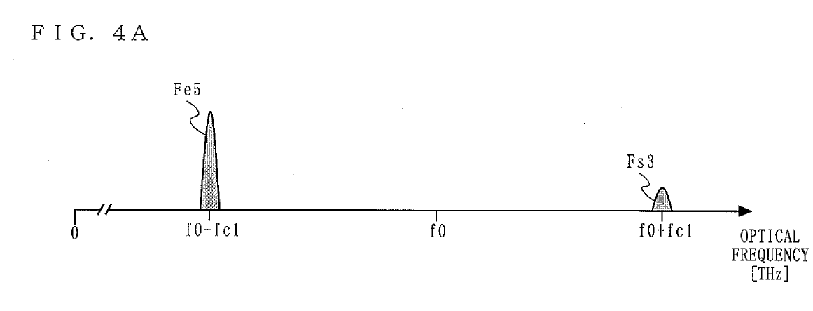

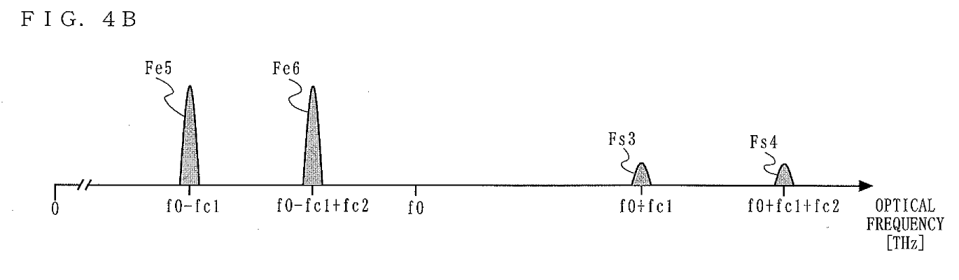

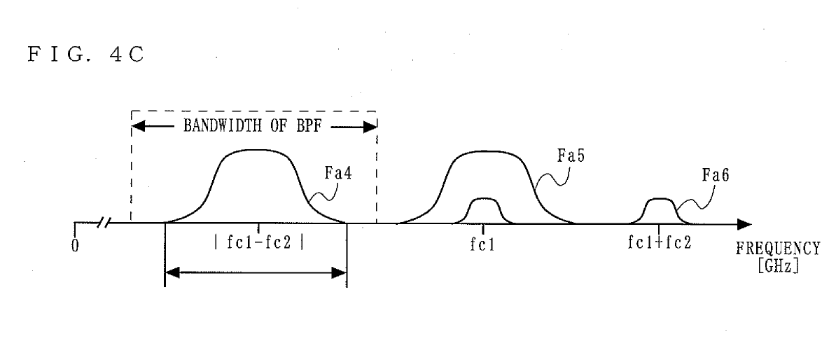

FIG. 4A is a view showing an example of an optical spectrum of the first optical signal Om1e outputted from the optical SSB-SC modulation section 103b. As shown in FIG. 4A, the first optical signal Om1e is an optical modulation signal including a frequency component Fe5 having a frequency (f0−fc1) and a vestigial single sideband component Fs3 having a frequency (f0+fc1).

To the optical SSB modulation section 104b, the first optical signal Om1e and a second electric signal E2 outputted from the second signal source 110 and having a predetermined frequency fc2 are inputted. The optical SSB modulation section 104b performs optical SSB modulation on the first optical signal Om1e in accordance with amplitude of the second electric signal E2, and outputs a resultant signal as a second optical signal Om1f.

FIG. 4B is a view showing an example of a spectrum of the second optical signal Om1f outputted from the optical SSB modulation section 104b. As shown in FIG. 4B, the second optical signal Om1f is an optical modulation signal including the frequency component Fe5 and a frequency component Fe6 having a center frequency of (f0−fc1+fc2). In addition, the second optical signal Om1f includes the vestigial single sideband component Fs3 and a vestigial single sideband component Fs4 having a center frequency of (f0+f1+f2).

FIG. 4C is a view showing an example of a spectrum of a difference beat signal Db outputted from the optical detection section 107. As shown in FIG. 4C, the difference beat signal Db includes an angle modulated signal component Fa4 having a center frequency of |fc1−fc2|, an angle modulated signal Fa5 having a center frequency of fc1 and including an unwanted wave component, and an unwanted wave component Fa6 having a center frequency of (fc1+fc2).

As shown in FIG. 4C, the angle modulated signal component Fa4 is a difference beat signal component obtained by down-converting the frequency component Fe6 to have the center frequency of |fc1−fc2|. The angle modulated signal Fa5 including the unwanted wave component is a difference beat signal component obtained by down-converting the frequency component Fe5 and the vestigial single sideband component Fs3 to have the center frequency of fc1 such that these components overlap with each other. The unwanted wave component Fa6 is a difference beat signal component obtained by down-converting the vestigial single sideband component Fs4 to have the center frequency of (fc1+fc2). Thus, the vestigial single sideband components do not overlap with the angle modulated signal component Fa4. Further, by selecting the frequencies fc1 and fc2 such that |fc1−fc2| becomes a desired carrier frequency, an angle modulated signal of the desired carrier frequency which is not affected by the vestigial single sideband components is obtained.

The angle modulator 20 outputs an angle modulated signal which does not include an unwanted frequency component by filtering only the angle modulated signal component Fa4 included in the difference beat signal Db shown in FIG. 4C. Thus, overlapping of other frequency components with the angle modulated signal component Fa4 has to be avoided. For that reason, where a signal bandwidth of the third optical signal Om2b is B, the bandwidth B, the frequency fc1, and the predetermined frequency fc2 need to satisfy a condition of |fc1−fc2|>B/2 and (2×fc2−fc1)<B.

As described above, by performing optical SSB-SC modulation on the non-modulated light L0 of the frequency f0 and performing optical SSB modulation on the optical SSB-SC modulated optical modulation signal, the angle modulator 20 can shift the vestigial sideband component generated at the optical SSB-SC modulation section to have a center frequency which is different from a desired center frequency. Thus, according to the angle modulator 20 according to the present embodiment, a distortion characteristic of a signal obtained by demodulating the angle modulated signal is prevented from deteriorating due to overlapping of an unwanted angle modulated signal component, which is generated by detecting light including a vestigial optical carrier component and a vestigial optical single sideband component, with a desired angle modulated signal component.

It is noted that as shown in FIG. 1, the angle modulator 20 may further include a filter 108. The filter 108 allows only an angle modulated signal component of the desired center frequency among the difference beat signal Db outputted from the optical detection section 107 to pass therethrough. The filter 108 is, for example, a band pass filter which extracts only the angle modulated signal component having the center frequency of |fc1−fc2| as indicated by a dashed line in FIG. 2D. By further including the filter 108, the angle modulator 20 removes a single sideband component of an angle modulated signal unwanted for the angle modulated signal having the desired carrier frequency, thereby providing a wideband angle modulated signal having an excellent noise characteristic and an excellent distortion characteristic.

For example, even when a low pass filter capable of extracting only an angle modulated signal having the center frequency of |fc1−fc2| is used as the filter 108, the same advantageous effect as that in the present embodiment is obtained.

In the first and second embodiments, as optical modulation, optical SSB modulation and optical SSB-SC modulation are used. However, the optical modulation in the present invention is not limited thereto. For example, optical DSB modulation, optical DSB-SC modulation, and the like may be used.

### Third Embodiment

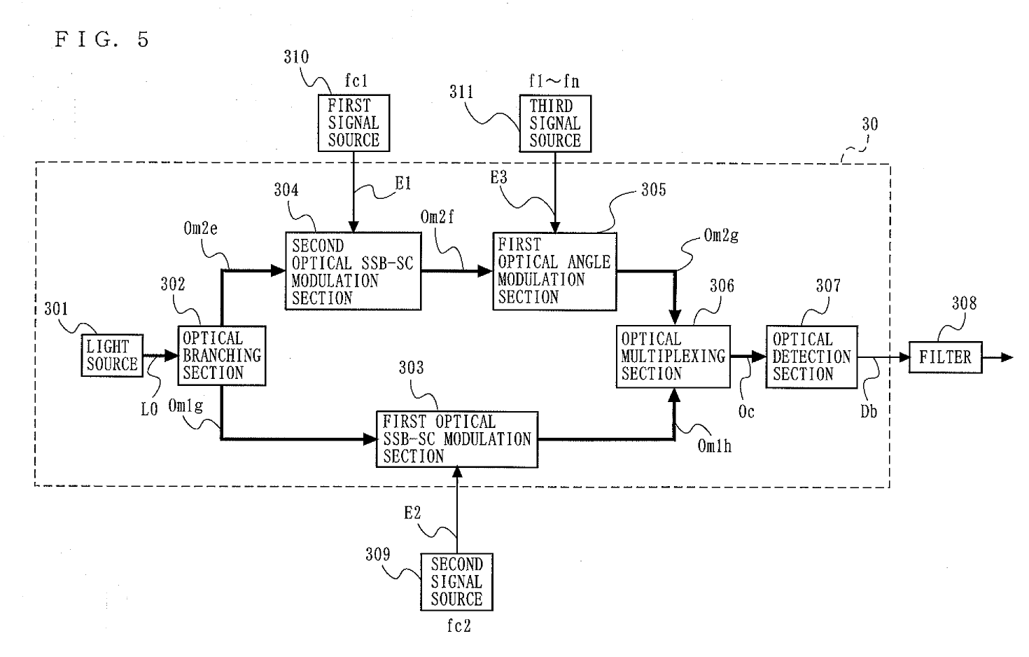

A third embodiment of the present invention will be described with reference to the figures. FIG. 5 is a block diagram showing a configuration of an angle modulator 30 according to the third embodiment of the present invention. As shown in FIG. 5, the angle modulator 30 includes a light source 301, an optical branching section 302, a first optical SSB-SC modulation section 303, a second optical SSB-SC modulation section 304, an optical angle modulation section 305, an optical multiplexing section 306, and an optical detection section 307. In the third embodiment, the first optical SSB-SC modulation section 303 functions as the first optical intensity modulation section recited in the CLAIMS, and the second optical SSB-SC modulation section 304 functions as the second optical intensity modulation section recited in the CLAIMS.

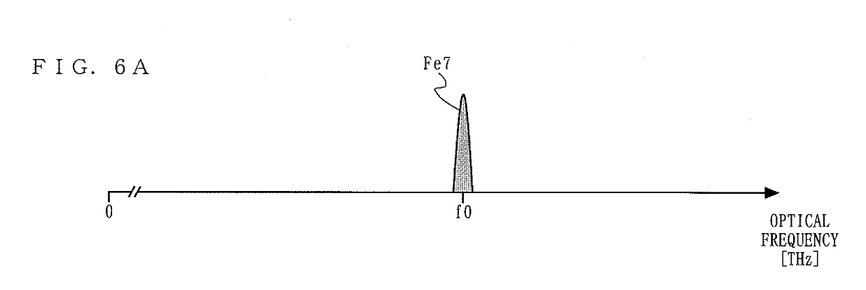

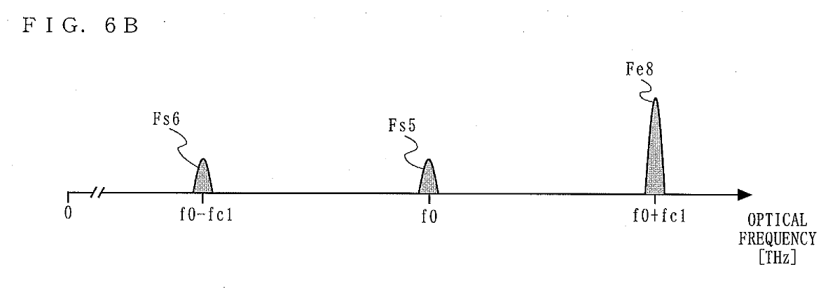

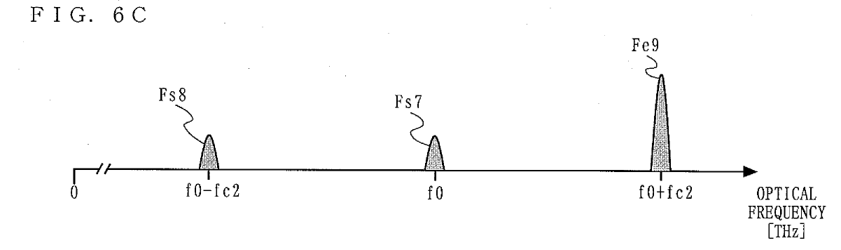

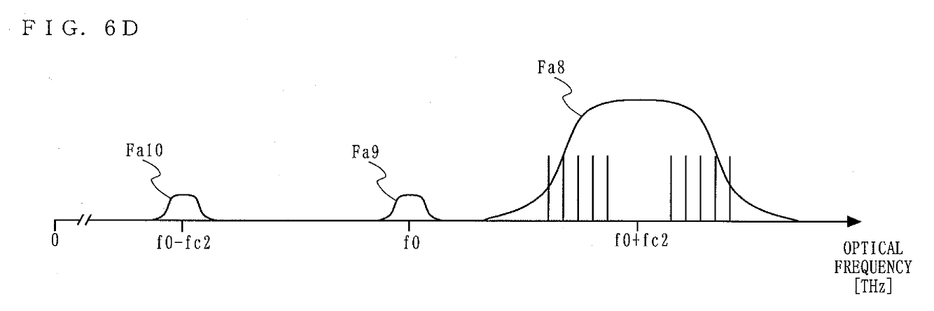

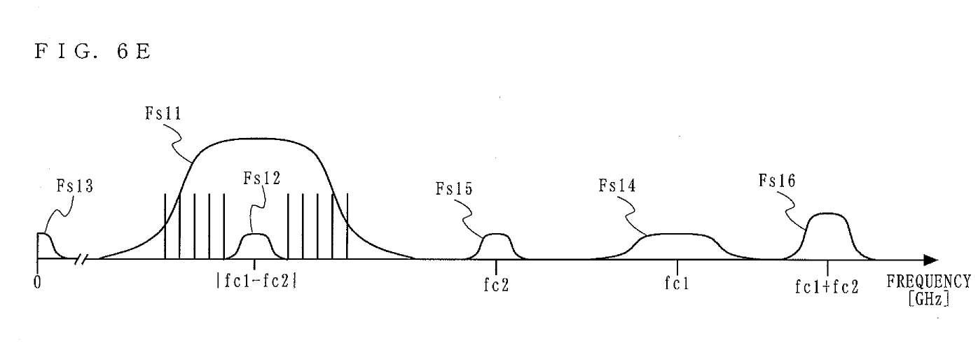

The light source 301 outputs non-modulated light L0 of a predetermined frequency f0. FIG. 6A is a schematic view showing an example of an optical spectrum of the non-modulated light L0 outputted from the light source 301.

The optical branching section 302 braches the non-modulated light L0 outputted from the light source 301, and outputs first light Om1g and second light Om2e.

To the first optical SSB-SC modulation section 303, the first light Om1g and a second electric signal E2 outputted from a second signal source 309 and having a predetermined frequency fc2 are inputted. The first optical SSB-SC modulation section 303 performs optical SSB-SC modulation on the first light Om1g in accordance with amplitude of the second electric signal E2, and outputs a modulated signal as a first optical signal Om1h.

FIG. 6B is a schematic view showing an example of an optical spectrum of the first optical signal Om1h. As shown in FIG. 6B, the first optical signal Om1h is an optical modulation signal including a desired optical sideband component Fe8, a vestigial optical carrier component Fs5, and a vestigial optical sideband component Fs6.

To the second optical SSB-SC modulation section 304, the second light Om2e and a first electric signal E1 outputted from a first signal source 310 and having a predetermined frequency fc1 are inputted. The second optical SSB-SC modulation section 304 performs optical SSB-SC modulation on the second light Om2e in accordance with amplitude of the first electric signal E1, and outputs a modulated signal as a second optical signal Om2f.

FIG. 6C is a schematic view showing an example of a spectrum of the second optical signal Om2f outputted from the second optical SSB-SC modulation section 304. As shown in FIG. 6C, the second optical signal Om2f is an optical modulation signal including a desired optical sideband component Fe9, a vestigial optical carrier component Fs7, and a vestigial optical sideband component Fs8.

To the optical angle modulation section 305, the second optical signal Om2f outputted from the second optical SSB-SC modulation section 304 and a third electric signal E3 outputted from a third signal source 311 are inputted. The third electric signal E3 is, for example, a signal obtained by frequency-multiplexing signals of frequencies f1 to fn. The optical angle modulation section 305 performs optical angle modulation on the second optical signal Om2f in accordance with amplitude of the inputted third electric signal E3, and outputs a resultant signal as a third optical signal Om2g.

FIG. 6D is a schematic view showing an example of a spectrum of the third optical signal Om2g outputted from the optical angle modulation section 305. As shown in FIG. 6D, the third optical signal Om2g is an optical modulation signal including an optical angle modulated signal Fa8 obtained by performing optical angle modulation on the desired optical sideband component Fe9, a vestigial optical angle modulated signal Fa9 obtained by performing optical angle modulation on the vestigial optical carrier component Fs7, and a vestigial optical angle modulated signal Fa10 obtained by performing optical angle modulation on the vestigial optical sideband component Fs8.

The optical multiplexing section 306 multiplexes the third optical signal Om2g outputted from the optical angle modulation section 305 and the first optical signal Om1h outputted from the first optical SSB-SC modulation section 303, and outputs a multiplexed optical signal.

The optical detection section 307 is constructed of, for example, a photodiode having a square-law detection characteristic. The optical detection section 307 performs optical homodyne detection of the multiplexed optical signal outputted from the optical multiplexing section 306 by using the square-law detection characteristic, and outputs an angle modulated signal as an inter-signal difference beat signal between the first optical signal Om1h and the third optical signal Om2g.

FIG. 6E is a schematic view showing an example of a spectrum of an angle modulated signal Db outputted from the optical detection section 307. As shown in FIG. 6E, a desired angle modulated signal Fs11 is a difference beat signal which is generated at a center frequency (|fc1−fc2|) by detecting the desired optical angle modulated signal Fa8 and the desired optical sideband component Fe8. Similarly, an unwanted angle modulated signal Fs12 is a signal which is generated at the center frequency (|fc1−fc2|) by detecting the vestigial optical angle modulated signal Fa10 and the vestigial optical sideband component Fs6. Similarly, an unwanted angle modulated signal Fs13 is a signal which is generated at a center frequency (0) by detecting the vestigial optical angle modulated signal Fa9 and the vestigial optical carrier component Fs5. Similarly, an unwanted angle modulated signal Fs14 is a signal which is generated at a center frequency (fc1) by detecting the desired optical angle modulated signal Fa9 and the desired optical sideband component Fe8, the vestigial optical angle modulated signal Fa9 and the vestigial optical sideband component Fs6, the desired optical sideband component Fe8 and the vestigial optical carrier component Fs5, and the vestigial optical carrier component Fs5 and the vestigial optical sideband component Fs6. Similarly, an unwanted angle modulated signal Fs15 is a signal which is generated at a center frequency (fc2) by detecting the desired optical angle modulated signal Fa8 and the vestigial optical carrier component Fs5, the desired optical angle modulated signal Fa8 and the vestigial optical angle modulated signal Fa9, and the vestigial optical angle modulated signal Fa9 and the vestigial optical angle modulated signal Fa10. Similarly, an unwanted angle modulated signal Fs16 is a signal which is generated at a center frequency (fc1+fc2) by detecting the desired optical angle modulated signal Fa8 and the vestigial optical sideband component Fs6, and the vestigial optical angle modulated signal Fa10 and the desired optical sideband component Fe8.

In other words, since an angle modulated signal which is generated from the vestigial optical sideband component Fs6 and the vestigial optical angle modulated signal Fa9 each of which is a factor for causing deterioration of a distortion characteristic in the conventional angle modulator 91 is generated at the center frequency (fc2) different from that of the desired angle modulated signal, it is considered that the angle modulated signal does not becomes a factor for causing deterioration of a distortion characteristic. Further, since the unwanted angle modulated signal Fs12 having the same center frequency as that of the desired angle modulated signal Fs11 and the unwanted angle modulated signal Fs13 generated at the center frequency (0) each are generated as a beat component based on vestigial components, their levels are suppressed to be extremely low. Therefore, an angle modulated signal of a desired carrier frequency, of which a distortion characteristic is not affected after this angle modulated signal is demodulated is obtained.

As described above, by performing optical SSB-SC modulation on the non-modulated light L0 of the frequency f0 and performing optical angle modulation on the optical SSB-SC modulated optical modulation signal, the angle modulator 30 can shift the center frequencies of the vestigial carrier component and the vestigial sideband component which are generated at the optical SSB-SC modulation section. Thus, according to the angle modulator 30 according to the present embodiment, the center frequency of the unwanted angle modulated signal which is generated from the vestigial optical carrier component and the vestigial optical sideband component can be different from the center frequency of the desired angle modulated signal. Further, since the unwanted angle modulated signal having the same center frequency as that of the desired angle modulated signal is a difference beat signal based on vestigial sideband components, a level of this signal can be extremely low. Therefore, according to the angle modulator 30 according to the present embodiment, the level of the unwanted angle modulated signal is reduced significantly with respect to the angle modulated signal having the desired carrier frequency, and a wideband angle modulated signal having an excellent noise characteristic and an excellent distortion characteristic can be provided.

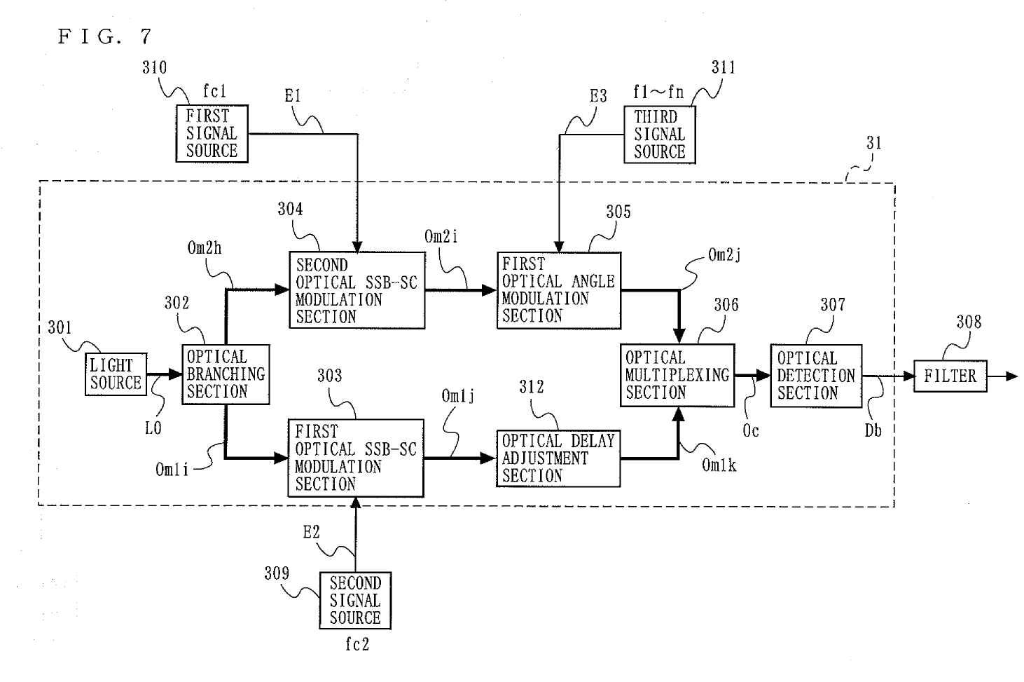

It is noted that an optical delay adjustment section may be further provided on one of or each of the paths. FIG. 7 is a block diagram showing a configuration of an angle modulator 31 in which an optical delay adjustment section 312 is inserted in a stage after the first optical SSB-SC modulation section 303. The optical delay adjustment section 312 performs adjustment such that propagation delay amounts of an optical signal Om1k and a third optical signal Om2j which are to be multiplexed by the optical multiplexing section 306 are precisely equalized with each other. Thus, phase noise of an angle modulated signal outputted from the optical detection section 307 can be cancelled in a state closer to an ideal state.

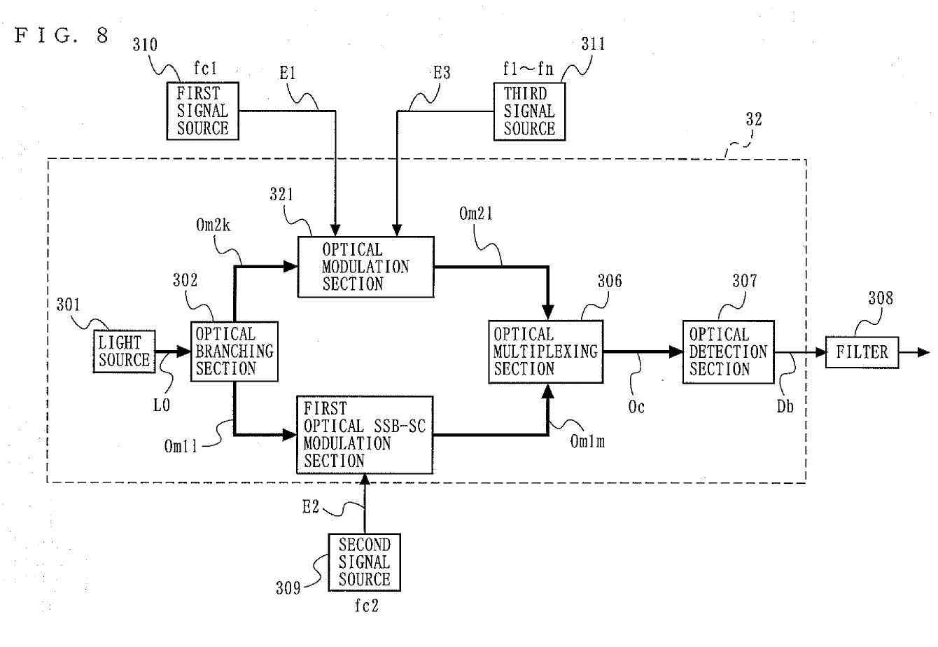

In the present embodiment, the second optical SSB-SC modulation section 304 and the optical angle modulation section 305 are provided independently of each other but may be integral with each other. FIG. 8 is a block diagram showing a configuration of an angle modulator 32 including an optical modulation section 321 into which the second optical SSB-SC modulation section 304 and the optical angle modulation section 305 of the angle modulator 30 according to the third embodiment are integrated. The angle modulator 32 includes a light source 301, an optical branching section 302, the optical modulation section 321, a first optical SSB-SC modulation section 303, an optical multiplexing section 306, and an optical detection section 307.

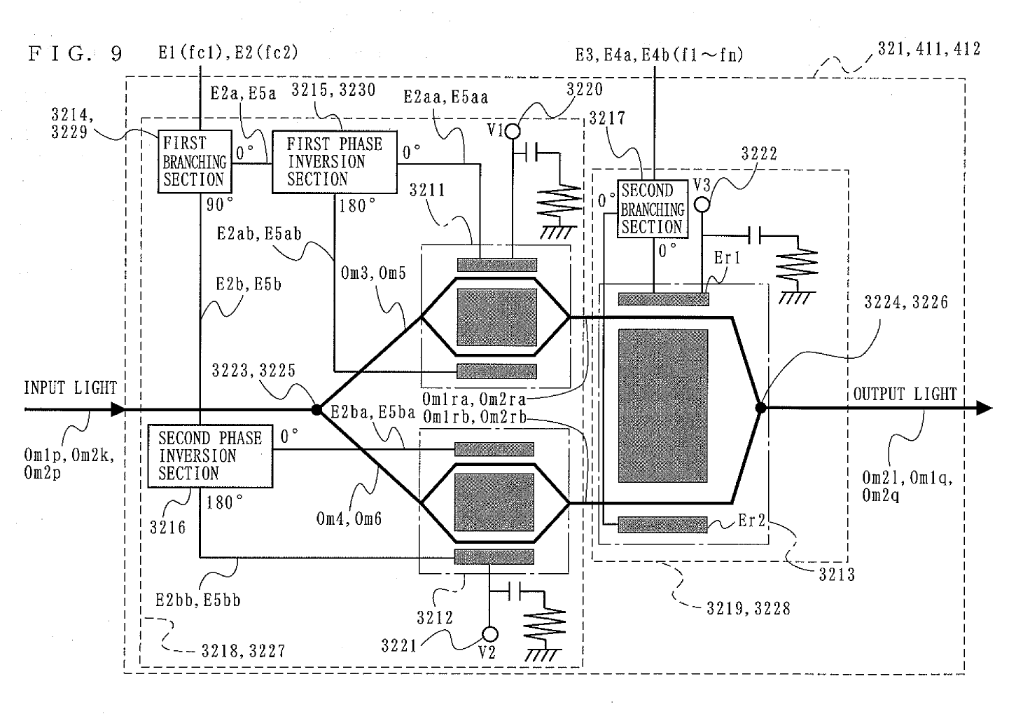

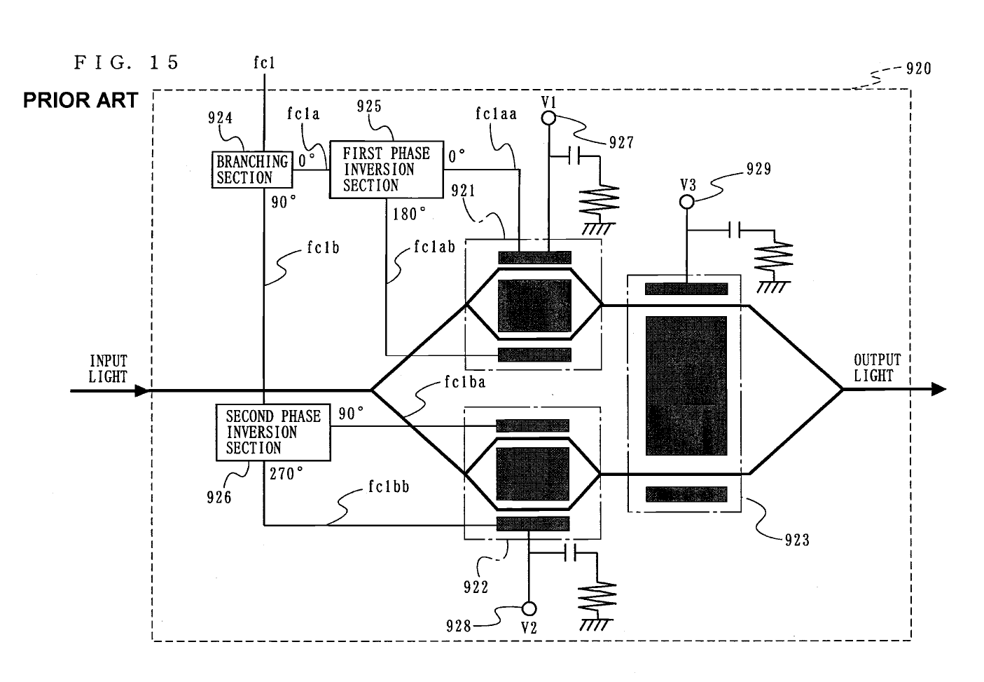

FIG. 9 is a schematic view showing an example of an internal configuration of the optical modulation section 321. As shown in FIG. 9, the optical modulation section 321 includes first to third MZ interferometers 3211 to 3213, a first branching section 3214, first and second phase inversion sections 3215 and 3216, and a second branching section 3217. As being obvious from FIG. 9, the optical modulation section 321 is different from the optical SSB-SC modulation section 920, of which an exemplary inner configuration is shown in FIG. 15, in further including the second branching section 3217.

The first MZ interferometer 3211 performs double-sideband optical intensity modulation (herein after, referred to as optical DSB modulation) on inputted light Om3, and outputs a resultant signal as a first optical intensity modulated signal Om2ra. The second MZ interferometer 3212 performs optical DSB modulation on inputted light Om4, and outputs a resultant signal as a second optical intensity modulated signal Om2rb. The first MZ interferometer 3211 and the second MZ interferometer 3212 constitute an optical intensity modulation section 3218, and function as the second optical intensity modulation section recited in the CLAIMS.

To the second branching section 3217, a third electric signal E3 outputted from a third signal source 311 and obtained by frequency-multiplexing signals of frequencies f1 to fn is inputted. The second branching section 3217 branches the third electric signal E3 into two electric signals so as to have the same phase, and outputs the branched electric signals. The two electric signals outputted from the second branching section 3217 are outputted to electrodes of the third MZ interferometer 3213, respectively. The first optical intensity modulated signal Om2ra and the second optical intensity modulated signal Om2rb which are inputted to the third MZ interferometer 3213 are subjected to optical angle modulation with the third electric signal E3, and their phases are adjusted with a third bias current V3. The second branching section 3217 and the third MZ interferometer 3213 constitute an optical angle modulation section 3219, and function as the first optical angle modulation section recited in the CLAIMS.

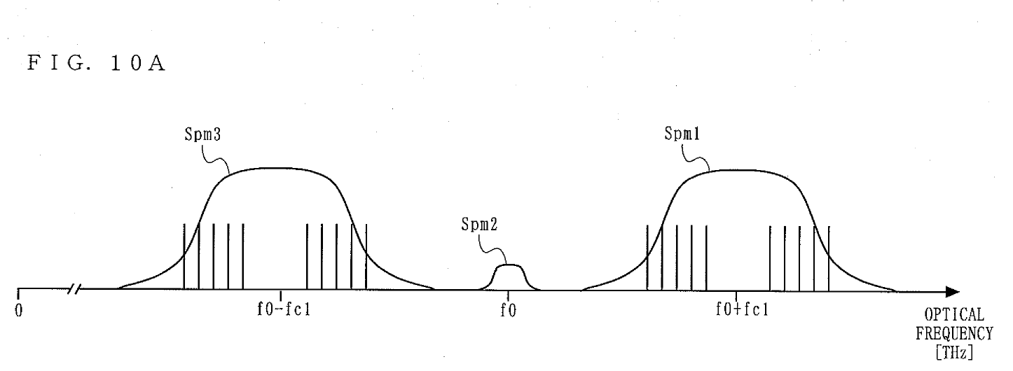

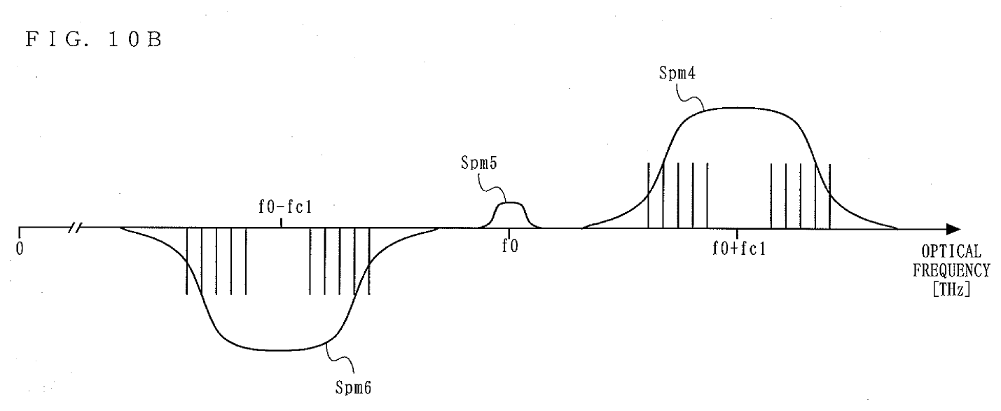

FIG. 10A is a schematic view showing an example of an optical spectrum of the first optical intensity modulated signal Om2ra which is outputted from the first MZ interferometer 3211 and then subjected to optical angle modulation at an electrode Er1 of the third MZ interferometer 3213. FIG. 10B is a schematic view showing an example of an optical spectrum of the second optical intensity modulated signal Om2rb which is outputted from the second MZ interferometer 3212 and then subjected to optical angle modulation at another electrode Er2 of the third MZ interferometer 3213.

A propagation delay amount of one third electric signal E3 outputted from the second branching section 3217 to reach one electrode of the third MZ interferometer 3213 is equalized with a propagation delay amount of the other third electric signal E3 outputted from the second branching section 3217 to reach the other electrode of the third MZ interferometer 3213. Further, a propagation delay amount of the one third electric signal E3 outputted from the second branching section 3217 to reach an output terminal of the third MZ interferometer 3213 as an optical signal through the one electrode of the third MZ interferometer 3213 where optical angle modulation is performed with the third electric signal E3 on the first optical intensity modulated signal Om2ra outputted from the first MZ interferometer 3211 is equalized with a propagation delay amount of the other third electric signal E3 outputted from the second branching section 3217 to reach the output terminal of the third MZ interferometer 3213 as an optical signal through the other electrode of the third MZ interferometer 3213 where optical angle modulation is performed with the third electric signal E3 on the second optical intensity modulated signal Om2rb outputted from the second MZ interferometer 3212. By doing so, an optical angle modulated signal Spm1 having a frequency of (f0+fc1) in FIG. 10A and an optical angle modulated signal Spm4 having a frequency of (f0+fc1) in FIG. 10B have the same phase. Thus, when these optical modulation signals are multiplexed, these optical modulation signals are reinforced by each other and outputted. On the other hand, an optical angle modulated signal Spm3 having a frequency of (f0−fc1) in FIG. 10A has a phase reverse to a phase of an optical angle modulated signal Spm6 having a frequency of (f0−fc1) in FIG. 10B. Thus, when these optical modulation signals are multiplexed, these optical modulation signals are canceled by each other. In this case, a spectrum of an optical modulation signal Om2l outputted from the third optical SSB-SC modulation section 321 is substantially the same as a spectrum of the third optical signal Om2g outputted from the optical angle modulation section 305 and shown in FIG. 6C. According to such a configuration, without providing the optical angle modulation section 305, the optical modulation section 321 can perform more efficient modulation, and a wideband angle modulated signal having an excellent noise characteristic and an excellent distortion characteristic can be provided.

It is noted that in the angle modulator 32, a delay adjustment section may be provided between the second branching section 3217 and one of or each of the electrodes of the third MZ interferometer 3213 for adjusting a propagation delay amount such that a propagation delay amount of one third electric signal E3 outputted from the second branching section 3217 to reach one electrode of the third MZ interferometer 3213 is equalized with a propagation delay amount of the other third electric signal E3 outputted from the second branching section 3217 to reach the other electrode of the third MZ interferometer 3213, or such that a propagation delay amount of the one third electric signal E3 outputted from the second branching section 3217 to reach the output terminal of the third MZ interferometer 3213 as an optical signal through the one electrode of the third MZ interferometer 3213 where optical angle modulation is performed with the third electric signal E3 on the first optical modulation signal Om2ra outputted from the first MZ interferometer 3211 is equalized with a propagation delay amount of the other third electric signal E3 outputted from the second branching section 3217 to reach the output terminal of the third MZ interferometer 3213 as an optical signal through the other electrode of the third MZ interferometer 3213 where optical angle modulation is performed with the third electric signal E3 on the second optical modulation signal Om2rb outputted from the second MZ interferometer 3212. By providing so, two propagation delay amounts can be more easily adjusted, and a more efficient optical angle modulated signal can be provided.

Further, as described above, in the angle modulator 32, an optical delay adjustment section may be further provided on one of or each of the above paths such that a propagation delay amount of light to pass through the path from the optical branching section 302 through the optical modulation section 321 to the optical multiplexing section 306 is equalized with a propagation delay amount of light to pass through the path from the optical branching section 302 through the first optical SSB-SC modulation section 303 to the optical multiplexing section 306. Thus, phase noise of an angle modulated signal outputted from the optical detection section 307 can be cancelled in a state closer to an ideal state.

In the present embodiment, where a signal bandwidth of the angle modulated signal Fs11 is B1, the bandwidth B1, the frequency fc1, and the frequency fc2 need to satisfy a condition of |fc1−fc2|≧B1/2. Thus, the frequency of the desired angle modulated signal Fs11 does not becomes equal to or smaller than a frequency (0), thereby obtaining an angle modulated signal of a desired carrier frequency, of which a distortion characteristic is not affected after this angle modulated signal is demodulated.

In the present embodiment, where a signal bandwidth of the angle modulated signal Fs14 is B2, when a relation between the frequency fc1 and the frequency fc2 satisfies fc1<fc2, by satisfying a condition of |fc1−fc2|+B1/2<fc1−B2/2, the unwanted angle modulated signal Fs14 does not overlap with the desired angle modulated signal Fs11, thereby obtaining an angle modulated signal of a desired carrier frequency, of which a distortion characteristic is not affected after this angle modulated signal is demodulated.

In the present embodiment, where a signal bandwidth of the angle modulated signal Fs15 is B3, when the relation between the frequency fc1 and the frequency fc2 satisfies fc1>fc2, by satisfying a condition of |fc1−fc2|+B1/2<fc2−B3/2, the unwanted angle modulated signal Fs15 does not overlap with the angle modulated signal Fs11, thereby obtaining an angle modulated signal of a desired carrier frequency, of which a distortion characteristic is not affected after this angle modulated signal is demodulated.

In the present embodiment, the angle modulated signals outputted from the optical detection section 307 include a signal of a frequency different from that of the desired angle modulated signal Fs11. However, when a lowpass filter capable of extracting only the desired angle modulated signal Fs11, the unwanted angle modulated signal Fs12, and the unwanted angle modulated signal Fs13 or a band pass filter capable of extracting only the desired angle modulated signal Fs11 and the unwanted angle modulated signal Fs12 are provided in a stage after the optical detection section 307, only a signal of the same frequency as that of the desired angle modulated signal Fs11 is outputted. Thus, an angle modulated signal having a further improved distortion characteristic after demodulated is obtained.

### Fourth Embodiment

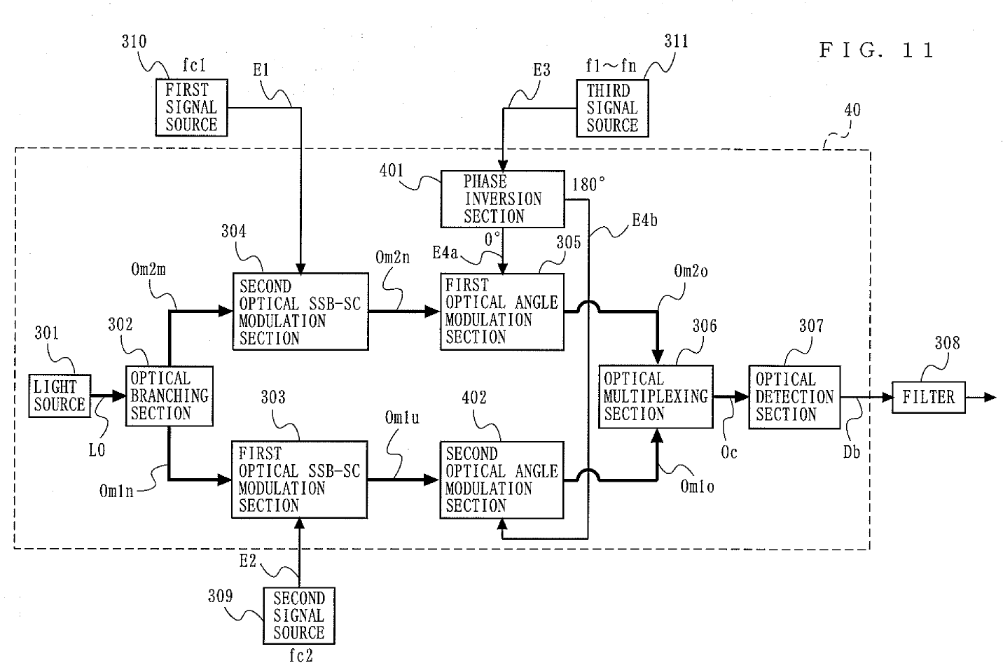

A fourth embodiment of the present invention will be described with reference to the figures. FIG. 11 is a block diagram showing a configuration of an angle modulator 40 according to the fourth embodiment of the present invention. The angle modulator 40 includes a light source 301, an optical branching section 302, a first optical SSB-SC modulation section 303, a second optical SSB-SC modulation section 304, a first optical angle modulation section 305, a phase inversion section 401, a second optical angle modulation section 402, an optical multiplexing section 306, and an optical detection section 307. In the fourth embodiment, the first optical SSB-SC modulation section 303 functions as the first optical intensity modulation section recited in the CLAIMS, and the second optical SSB-SC modulation section 304 functions as the second optical intensity modulation section recited in the CLAIMS.

The angle modulator 40 according to the fourth embodiment is different from the angle modulator 30 according to the aforementioned third embodiment in including the phase inversion section 401 and the second optical angle modulation section 402. A basic operation of the angle modulator 40 is substantially the same as that of the angle modulator 30. Thus, the same components as those of the angle modulator 30 are designated by the same reference characters, and the description thereof will be omitted. The operation of the angle modulator 40, mainly, operations of the phase inversion section 401 and the second optical angle modulation section 402 will be described.

In the angle modulator 40, the phase inversion section 401 generates from a third electric signal E3 outputted from a third signal source 311 an electric signal E4a having the same phase as that of the third electric signal E3 and an inversion signal E4b having a phase different from that of the third electric signal E3 by 180°, and inputs the generated electric signal E4a and the inversion signal E4b to the first optical angle modulation section 305 and the second optical angle modulation section 402, respectively.

To the first optical angle modulation section 305, a second optical signal Om2n outputted from the second optical SSB-SC modulation section 304 and the electric signal E4a outputted from the phase inversion section 401 are inputted. The first optical angle modulation section 305 performs optical angle modulation on the second optical signal Om2n in accordance with amplitude of the inputted electric signal E4a, and outputs a resultant signal as a third optical signal Om2o. To the second optical angle modulation section 402, a first optical signal Om1u outputted from the first optical SSB-SC modulation section 303 and the inversion signal E4b outputted from the phase inversion section 401 are inputted. The second optical angle modulation section 402 performs optical angle modulation on the first optical signal Om1u in accordance with amplitude of the inputted inversion signal E4b, and outputs a resultant signal as a fourth optical signal Om1o.

A propagation delay amount of the electric signal E4a outputted from the phase inversion section 401 to reach the first optical angle modulation section 305 is equalized with a propagation delay amount of the inversion signal E4b outputted from the phase inversion section 401 to reach the second optical angle modulation section 402. Further, a propagation delay amount of the electric signal E4a outputted from the phase inversion section 401 to reach the optical multiplexing section 306 as the third optical signal Om2o through the first optical angle modulation section 305 is equalized with a propagation delay amount of the inversion signal E4b outputted from the phase inversion section 401 to reach the optical multiplexing section 306 as the fourth optical signal Om1o through the second optical angle modulation section 402.

A reason for providing the second optical angle modulation section 402 will be described. Generally, in an optical angle modulation section, an optical waveguide is often provided on a crystal substrate such as a lithium niobate substrate, and the like. Such an optical modulator has a low rate of change in an optical phase (an optical frequency) with respect to an input voltage, and thus needs a great voltage swing as a modulation signal. Meanwhile, an output of an electric amplifier for amplifying a modulation signal is saturated at a certain level, and it is hard to improve performance of the electric amplifier. For that reason, as in the present embodiment, the third electric signal E3 is branched by the phase inversion section 401, and branched signals are treated with signal processing such as electric amplification, and the like and then inputted to optical angle modulation sections, respectively. By such a configuration, a burden on the electric amplifier for driving an optical modulation section can be reduced. Further, shift amounts of phases of the third optical signal Om2o and the fourth optical signal Om1o which are to be multiplexed by the optical multiplexing section 306 can be the same as each other. Thus, the angle modulator 40 has a configuration capable of performing push-pull modulation, and a shift amount of a phase of an angle modulated signal outputted from the optical detection section 307 can be increased more efficiently.

As described above, according to the angle modulator 40 according to the fourth embodiment, by providing two optical angle modulation sections, the shift amount of the phase of the angle modulated signal can be increased more efficiently in addition to the effects obtained by the angle modulator 30 according to the third embodiment.

Similarly as in the aforementioned first embodiment, in the angle modulator 40, an optical phase adjustment section may be further provided on one of or each of the above paths such that a propagation delay amount of the electric signal E4a outputted from the phase inversion section 401 to reach the first optical angle modulation section 305 is equalized with a propagation delay amount of the inversion signal E4b outputted from the phase inversion section 401 to reach the second optical angle modulation section 402, or such that a propagation delay amount of light to pass through the path from the optical branching section 302 through the second optical SSB-SC modulation section 304 and the first optical angle modulation section 305 to the optical multiplexing section 306 corresponds to a propagation delay amount of light to pass through the path from the optical branching section 302 through the first optical SSB-SC modulation section 303 and the second optical angle modulation section 402 to the optical multiplexing section 306. Thus, phase noise of an angle modulated signal outputted from the optical detection section 307 can be cancelled in a state closer to an ideal state.

For that reason, although not shown in the figure, the angle modulator 40 according to the present embodiment may include amplifiers which are provided between the phase inversion section 401 and the first optical angle modulation section 305 and between the phase inversion section 401 and the second optical angle modulation section 402 for amplifying the electric signal E4a and the inversion signal E4b outputted from the phase inversion section 401, respectively.

Further, similarly as in the aforementioned first embodiment, in the angle modulator 40, the optical SSB-SC modulation section and the optical angle modulation section may be integral with each other. More specifically, the first optical SSB-SC modulation section 303 and the second optical angle modulation section 402 may be integral with each other, and the second optical SSB-SC modulation section 304 and the first optical angle modulation section 305 may be integral with each other.

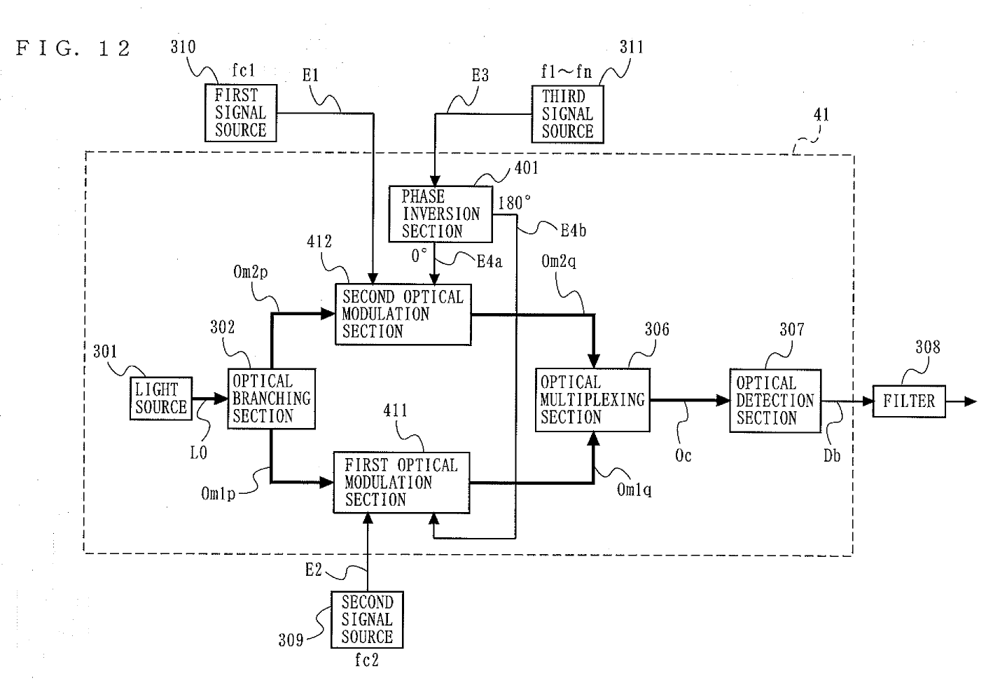

FIG. 12 is a block diagram showing a configuration of an angle modulator 41 in which the first optical SSB-SC modulation section 303 and the second optical angle modulation section 402 are integrated into a first optical modulation section 411 and the second optical SSB-SC modulation section 304 and the first optical angle modulation section 305 are integrated into a second optical modulation section 412. The first optical modulation section 411 and the second optical modulation section 412 have the same configurations as that of the optical modulation section 321 shown in FIG. 9, and hence the description thereof will be omitted. By such a configuration, the angle modulator 41 is capable of performing more efficient optical angle modulation at the first optical modulation section 411 and the second optical modulation section 412 without providing the first optical angle modulation section 305 and the second optical angle modulation section 402, and can provide a wideband angle modulated signal having an excellent noise characteristic and an excellent distortion characteristic. In the angle modulator 41, an optical intensity modulation section 3227 included in the first optical modulation section 411 functions as the first optical intensity modulation section recited in the CLAIMS, and an optical intensity modulation section 3218 included in the second optical modulation section 412 functions as the second optical intensity modulation section recited in the CLAIMS. Further, an optical angle modulation section 3219 included in a second optical modulation section functions as the first optical angle modulation section recited in the CLAIMS.

Similarly as in the aforementioned first embodiment, in the angle modulator 41, an optical phase adjustment section may be further provided on one of or each of the above paths such that a propagation delay amount of light to pass through the path from the optical branching section 102 through the first optical modulation section 411 to the optical multiplexing section 306 is equalized to a propagation delay amount of light to pass through the path from the optical branching section 302 through the second optical modulation section 412 to the optical multiplexing section 306. Thus, phase noise of an angle modulated signal outputted from the optical detection section 307 can be cancelled in a state closer to an ideal state.

Although not shown in the figure, similarly as the angle modulator 40, the angle modulator 41 may include amplifiers which are provided between the phase inversion section 401 and the first optical modulation section 411 and between the phase inversion section 401 and the second optical modulation section 412 for amplifying the electric signal E4a and the inversion signal E4b outputted from the phase inversion section 401, respectively.

Similarly as in the aforementioned third embodiment, in the angle modulator 40 and the angle modulator 41 according to the present embodiment, where the signal bandwidth of the angle modulated signal Fs11 is B1, the bandwidth B1, the frequency fc1, and the frequency fc2 need to satisfy a condition of |fc1−fc2|>B1/2. Thus, a frequency of a signal having the same center frequency as that of the desired angle modulated signal Fs11 does not become equal to or smaller than a frequency (0), thereby obtaining an angle modulated signal of a desired carrier frequency, of which a distortion characteristic is not affected after this angle modulated signal is demodulated. Further, where the signal bandwidth of the angle modulated signal Fs14 is B2, when a relation between the frequency fc1 and the frequency fc2 satisfies fc1<fc2, by satisfying a condition of |fc1−fc2|+B1/2<fc1−B2/2, the unwanted angle modulated signal Fs14 does not overlap with the desired angle modulated signal Fs11, thereby obtaining an angle modulated signal of a desired carrier frequency, of which a distortion characteristic is not affected after this angle modulated signal is demodulated.

In the present embodiment, where the signal bandwidth of the angle modulated signal Fs15 is B3, when the relation between the frequency fc1 and the frequency fc2 satisfies fc1>fc2, by satisfying the condition of |fc1−fc2|+B1/2<fc2−B3/2, the unwanted angle modulated signal Fs15 does not overlap with the desired angle modulated signal Fs11, thereby obtaining an angle modulated signal of a desired carrier frequency, of which a distortion characteristic is not affected after this angle modulated signal is demodulated.

Similarly as in the aforementioned first embodiment, in the angle modulator 40 and the angle modulator 41 according to the present embodiment, the angle modulated signals outputted from the optical detection section 307 include a signal having a frequency different from that of the desired angle modulated signal Fs11. However, when a lowpass filter capable of extracting only the desired angle modulated signal Fs11, the unwanted angle modulated signal Fs12, and the unwanted angle modulated signal Fs13 or a band pass filter capable of extracting only the desired angle modulated signal Fs11 and the unwanted angle modulated signal Fs12 are provided in a stage after the optical detection section 307, only a signal of the same frequency as that of the desired angle modulated signal Fs11 is outputted. Thus, an angle modulated signal having a further improved distortion characteristic after demodulated is obtained.

### INDUSTRIAL APPLICABILITY

The angle modulator according to the present invention has an excellent noise characteristic as well as an excellent distortion characteristic, and hence is useful for, for example, a video signal distribution system, and the like. Further, the angle modulator according to the present invention is applicable to, for example, millimeter-wave and microwave generating apparatuses, and the like.

1. An angle modulator for converting an input signal into an angle modulated signal, the angle modulator comprising:
a light source;
an optical branching section for branching light outputted from the light source into light propagating along a first path and light propagating along a second path;
a first optical intensity modulation section provided on the first path for performing intensity modulation on inputted light with a second electric signal of a frequency fc2;
a first optical angle modulation section provided on the second path for performing angle modulation on inputted light with an inputted signal;
an optical multiplexing section for multiplexing the light propagating along the first path and the light propagating along the second path at ends of the first path and the second path;
a second optical intensity modulation section provided in a stage prior to either the first optical intensity modulation section or the first optical angle modulation section for performing intensity modulation on inputted light with a first electric signal of a frequency fc1 different from the frequency fc2, and outputting intensity modulated light; and
an optical detection section having a square-law detection characteristic for converting an optical signal outputted from the optical multiplexing section into an angle modulated signal.

2. The angle modulator according to claim 1, wherein
the second optical intensity modulation section is provided in a stage prior to the first optical intensity modulation section for performing optical SSB modulation on inputted light, and
the first optical intensity modulation section performs optical SSB-SC modulation on optical SSB modulated light.

3. The angle modulator according to claim 2, wherein
where a bandwidth of an optical signal outputted from the optical angle modulation section is B,

|fc1−fc2|>B/2 and
2×fc2−fc1>B
are satisfied.

4. The angle modulator according to claim 1, wherein
the second optical intensity modulation section is provided in a stage prior to the first optical intensity modulation section for performing optical SSB-SC modulation on inputted light, and
the first optical intensity modulation section performs optical SSB modulation on optical SSB-SC modulated light.

5. The angle modulator according to claim 4, wherein
where a bandwidth of an optical signal outputted from the optical angle modulation section is B,

|fc1−fc2|>B/2 and
2×fc2−fc1>B
are satisfied.

6. The angle modulator according to claim 1, wherein the second optical intensity modulation section is provided in a stage prior to the first optical angle modulation section.

7. The angle modulator according to claim 6, wherein
the first optical intensity modulation section performs optical SSB-SC modulation on inputted light,
the second optical intensity modulation section performs optical SSB-SC modulation on inputted light, and
the first optical angle modulation section performs angle modulation on optical SSB-SC modulated light with the input signal.

8. The angle modulator according to claim 7, further comprising an optical delay adjustment section provided in a stage after the first optical intensity modulation section for delaying propagation of the light propagating along the first path such that a propagation delay amount of the light propagating along the first path is equalized with a propagation delay amount of the light propagating along the second path.

9. The angle modulator according to claim 6, wherein
the second optical intensity modulation section includes:
a first optical DSB modulation section for performing optical DSB modulation on the branched light propagating along the second path with the first electric signal and with an electric signal obtained by shifting a phase of the first electric signal by 180°; and
a second optical DSB modulation section for performing optical DSB modulation on the branched light propagating along the second path with an electric signal obtained by shifting the phase of the first electric signal by 90° and with an electric signal obtained by further shifting the phase of the first electric signal by 180° after shifting the phase of the first electric signal by 90°, and
the first optical angle modulation section performs optical angle modulation on light outputted from the first optical DSB modulation section and light outputted from the second optical DSB modulation section with the input signal, respectively, and multiplexes light obtained by performing optical angle modulation on the light outputted from the first optical DSB modulation section and light obtained by performing optical angle modulation on the light outputted from the second optical DSB modulation section.

10. The angle modulator according to claim 6, further comprising:
a phase inversion section for branching the input signal into an in-phase signal having the same phase as a phase of the input signal and a reverse-phase signal obtained by inverting the phase of the input signal; and
a second optical angle modulation section provided in a stage after the first optical intensity modulation section for performing optical angle modulation on inputted light with an inputted signal,
wherein the first optical angle modulation section performs angle modulation on inputted light with the in-phase signal.

11. The angle modulator according to claim 10, wherein
the first optical intensity modulation section performs optical SSB-SC modulation on inputted light, and
the second optical intensity modulation section performs optical SSB-SC modulation on inputted light.

12. The angle modulator according to claim 10, wherein
the second optical intensity modulation section includes:
a first optical DSB modulation section for performing optical DSB modulation on the branched light propagating along the second path with the first electric signal and with an electric signal obtained by shifting a phase of the first electric signal by 180°; and
a second optical DSB modulation section for performing optical DSB modulation on the branched light propagating along the second path with an electric signal obtained by shifting the phase of the first electric signal by 90° and with an electric signal obtained by further shifting the phase of the first electric signal by 180° after shifting the phase of the first electric signal by 90°,
the first optical intensity modulation section includes:
a third optical DSB modulation section for performing optical DSB modulation on the branched light propagating along the first path with the second electric signal and with an electric signal obtained by shifting a phase of the second electric signal by 180°; and
a fourth optical DSB modulation section for performing optical DSB modulation on the branched light propagating along the first path with an electric signal obtained by shifting the phase of the second electric signal by 90° and with an electric signal obtained by further shifting the phase of the second electric signal by 180° after shifting the phase of the second electric signal by 90°,
the first optical angle modulation section performs optical angle modulation on light outputted from the first optical DSB modulation section and light outputted from the second optical DSB modulation section with the in-phase signal, respectively, and multiplexes light obtained by optical angle modulation on the light outputted from the first optical DSB modulation section and light obtained by optical angle modulation on the light outputted from the second optical DSB modulation section, and
the second optical angle modulation section performs optical angle modulation on light outputted from the third optical DSB modulation section and light outputted from the fourth optical DSB modulation section with the reverse-phase signal, respectively, and multiplexes light obtained by performing optical angle modulation on the light outputted from the third optical DSB modulation section and light obtained by performing optical angle modulation on the light outputted from the fourth optical DSB modulation section.

13. The angle modulator according to claim 7, wherein
where among angle modulated signals outputted from the optical detection section, a bandwidth of an angle modulated signal having a center frequency of |fc1−fc2| is B1 and a bandwidth of an angle modulated signal having a center frequency of fc1 is B2,
when fc1<fc2,

|fc1−fc2|≧B1/2 and

|fc1−fc2|+B1/2<fc1−B2/2
are satisfied.

14. The angle modulator according to claim 7, wherein
where among angle modulated signals outputted from the optical detection section, a bandwidth of an angle modulated signal having a center frequency of |fc1−fc2| is B1 and a bandwidth of an angle modulated signal having a center frequency of fc2 is B3,
when fc1>fc2,

|fc1−fc2|≧B1/2 and

|fc1−fc2|+B1/2<fc2−B3/2
are satisfied.

15. The angle modulator according to claim 1, further comprising a filter for extracting a signal component in a frequency band including a frequency |fc1−fc2| from the angle modulated signal outputted from the optical detection section.

16. The angle modulator according to 8, wherein
where among angle modulated signals outputted from the optical detection section, a bandwidth of an angle modulated signal having a center frequency of |fc1−fc2| is B1 and a bandwidth of an angle modulated signal having a center frequency of fc1 is B2,
when fc1<fc2,

|fc1−fc2|≧B1/2 and

|fc1−fc2|+B1/2<fc1−B2/2
are satisfied.

17. The angle modulator according to 9, wherein
where among angle modulated signals outputted from the optical detection section, a bandwidth of an angle modulated signal having a center frequency of |fc1−fc2| is B1 and a bandwidth of an angle modulated signal having a center frequency of fc1 is B2,
when fc1<fc2,

|fc1−fc2|≧B1/2 and

|fc1−fc2|+B1/2<fc1−B2/2
are satisfied.

18. The angle modulator according to claim 8, wherein
where among angle modulated signals outputted from the optical detection section, a bandwidth of an angle modulated signal having a center frequency of |fc1−fc2| is B1 and a bandwidth of an angle modulated signal having a center frequency of fc2 is B3,
when fc1>fc2,

|fc1−fc2|≧B1/2 and

|fc1−fc2|+B1/2<fc2−B3/2
are satisfied.

19. The angle modulator according to claim 9, wherein
where among angle modulated signals outputted from the optical detection section, a bandwidth of an angle modulated signal having a center frequency of |fc1−fc2| is B1 and a bandwidth of an angle modulated signal having a center frequency of fc2 is B3,
when fc1>fc2,

|fc1−fc2|≧B1/2 and

|fc1−fc2|+B1/2<fc2−B3/2
are satisfied.
